(19) United States
(12) Patent Application Publication
(10) Pub. No.: US 2026/0088586 A1
(43) Pub. Date: Mar. 26, 2026

(54) LASER MODULE

(71) Applicant: HISENSE LASER DISPLAY CO., LTD., Qingdao (CN)

(72) Inventors: Mengxiao GUO, Qingdao (CN); Zinan ZHOU, Qingdao (CN); Xin ZHANG, Qingdao (CN); Youliang TIAN, Qingdao (CN); Yao LU, Qingdao (CN)

(73) Assignee: HISENSE LASER DISPLAY CO., LTD., Qingdao (CN)

(21) Appl. No.: 19/403,961

(22) Filed: Nov. 30, 2025

Related U.S. Application Data
(63) Continuation of application No. PCT/CN2024/096160, filed on May 29, 2024.

(30) Foreign Application Priority Data
Jun. 16, 2023 (CN) 202310723380.0
Jun. 28, 2023 (CN) 202310773058.9
Jun. 28, 2023 (CN) 202321670807.7
Sep. 5, 2023 (CN) 202322406540.7

(51) Int. Cl. H01S 5/024; H01S 5/02; H01S 5/02253; H01S 5/02255; H01S 5/0237

(52) U.S. Cl. CPC H01S 5/02469; H01S 5/0213; H01S 5/02253; H01S 5/02255; H01S 5/0237

(57) ABSTRACT

A laser is provided, which includes a frame, a substrate, heat sinks, light-emitting chips, and protective devices. The frame and the heat sinks are fixed to the substrate. The heat sinks, the light-emitting chips, and the protective devices are located inside the frame. The light-emitting chips and the protective devices are fixed to the heat sinks, and the light-emitting chip and the corresponding protective device have a spacing therebetween in a length direction of the heat sink.

### CROSS-REFERENCE TO RELATED APPLICATIONS

The present application is a continuation application of the International Patent Application No. PCT/CN2024/096160 filed on May 29, 2024. The international application claims priority to the Chinese Patent Application No. 202310723380.0 filed on Jun. 16, 2023 and entitled “LIGHT-EMITTING DEVICE”, the Chinese Patent Application No. 202310773058.9 filed on Jun. 28, 2023 and entitled “LASER”, the Chinese Utility Model application No. 202321670807.7 filed on Jun. 28, 2023 and entitled “LASER”, and the Chinese Utility Model application No. 202322406540.7 filed on Sep. 5, 2023 and entitled “LASER MODULE”. The entire contents of all the above applications are incorporated herein by reference.

### TECHNICAL FIELD

The present disclosure relates to the field of optoelectronic technologies, and in particular, to a laser module.

### BACKGROUND

With the development of an optoelectronic technology, a laser module has been widely used.

In the related art, a laser is an important component of the laser module. The laser includes a light-emitting chip and a protective device. The light-emitting chip and the protective device are spaced apart. The light-emitting chip may generate heat during laser emission. Moreover, as the light-emitting chip continues to emit light, accumulated heat easily causes a temperature of the light-emitting chip to exceed an upper limit of a normal operating temperature, which may affect the light-emitting effect of the light-emitting chip and may also cause damage to the light-emitting chip.

### SUMMARY

In one aspect, the present disclosure provides a laser module, including a laser. The laser includes a frame, a substrate, heat sinks, light-emitting chips, and protective devices. The frame and the heat sinks are fixed to the substrate. The heat sinks, the light-emitting chips, and the protective devices are located inside the frame. The light-emitting chips and the protective devices are fixed to the heat sinks. The light-emitting chip and the corresponding protective device have a spacing therebetween in a length direction of the heat sink. Orthographic projections of the light-emitting chip and the protective device in the length direction of the heat sink at least partially overlap or are spaced apart.

In another aspect, the present disclosure provides a laser module, including a laser. The laser includes a frame, a substrate, heat sinks, light-emitting chips, and protective devices. The substrate is made of diamond copper, the heat sink is made of diamond, and a thickness of the heat sink ranges from 0.2 mm to 0.4 mm. The frame and the heat sinks are fixed to the substrate. The heat sinks, the light-emitting chips, and the protective devices are located inside the frame. The light-emitting chips and the protective devices are fixed to the heat sinks.

Details of one or more embodiments of the present disclosure are set forth in the accompanying drawings and description below. Other features, objects, and advantages of the disclosure will become apparent from the description, the drawings, and the claims.

### BRIEF DESCRIPTION OF THE DRAWINGS

In order to more clearly illustrate the technical solutions in embodiments of the present disclosure, the accompanying drawings used in the description of the embodiments will be briefly introduced below. It is apparent that the accompanying drawings in the following description are only some embodiments of the present disclosure, and other drawings can be obtained by those of ordinary skill in the art from the provided drawings without creative efforts.

FIG. 1 is a schematic structural diagram of a light-emitting device in the related art according to an embodiment of the present disclosure.

FIG. 2 is a schematic structural diagram of a light-emitting device in the related art according to an embodiment of the present disclosure.

FIG. 3 is a schematic structural diagram of a light-emitting device according to an embodiment of the present disclosure.

FIG. 4 is a schematic diagram of a partial structure of a light-emitting device according to an embodiment of the present disclosure.

FIG. 5 is a schematic diagram of a partial structure of a light-emitting device according to an embodiment of the present disclosure.

FIG. 6 is a schematic diagram of a partial structure of a light-emitting device according to an embodiment of the present disclosure.

FIG. 7 is a schematic cross-sectional view of a light-emitting device according to an embodiment of the present disclosure.

FIG. 8 is a schematic diagram of a partial structure of a light-emitting device according to an embodiment of the present disclosure.

FIG. 9 is a schematic diagram of a partial structure of a light-emitting device according to an embodiment of the present disclosure.

FIG. 10 is a schematic diagram of connections of an electrical probe with a heat sink and a light-emitting chip in the related art according to an embodiment of the present disclosure.

FIG. 11 is a schematic diagram of connections of an electrical probe with a heat sink and a light-emitting chip according to an embodiment of the present disclosure.

FIG. 12 is a schematic diagram of connections of an electrical probe with a heat sink and a light-emitting chip according to an embodiment of the present disclosure.

FIG. 13 is a schematic diagram of a partial structure of a light-emitting device in the related art according to an embodiment of the present disclosure.

FIG. 14 is a schematic diagram of a partial structure of a light-emitting device according to an embodiment of the present disclosure.

FIG. 15 is a schematic diagram of a partial structure of a light-emitting device according to an embodiment of the present disclosure.

FIG. 16 is a schematic diagram of a partial structure of a light-emitting device in the related art according to an embodiment of the present disclosure.

FIG. 17 is a schematic diagram of a partial structure of a light-emitting device according to an embodiment of the present disclosure.

FIG. 18 is a side view of a laser according to another embodiment of the present disclosure.

FIG. 19 is a diagram of an optical path of laser light emitted from a light-emitting chip in a laser according to another embodiment of the present disclosure.

FIG. 20 is a diagram of an optical path of laser light emitted from a light-emitting chip when a heat sink has a smaller thickness according to another embodiment of the present disclosure.

FIG. 21 is a diagram of an optical path of laser light emitted from another light-emitting chip according to another embodiment of the present disclosure.

FIG. 22 is a schematic diagram of a light-emitting chip fixed to a heat sink according to another embodiment of the present disclosure.

FIG. 23 is a schematic diagram of a simulation of heat generation of a light-emitting chip according to another embodiment of the present disclosure.

FIG. 24 is a schematic structural diagram of a heat sink according to another embodiment of the present disclosure.

FIG. 25 is a top view of another laser according to another embodiment of the present disclosure.

FIG. 27 is a schematic cross-sectional view of another laser according to another embodiment of the present disclosure.

FIG. 26 is a cross-sectional view of the laser shown in FIG. 8 at A-A′;

FIG. 28 is a schematic cross-sectional view of yet another laser according to another embodiment of the present disclosure.

FIG. 29 is a schematic diagram of a cross-sectional structure of a laser module in the related art according to yet another embodiment of the present disclosure.

FIG. 30 is a schematic diagram of a 3D structure of a laser module in one or more embodiments according to yet another embodiment of the present disclosure.

FIG. 31 is a schematic diagram of a plan structure of a laser module in one or more embodiments according to yet another embodiment of the present disclosure.

FIG. 32 is a schematic diagram of a cross-sectional structure of a laser module in one or more embodiments according to yet another embodiment of the present disclosure.

FIG. 33 is a schematic diagram of a 3D structure of a laser module in one or more other embodiments according to yet another embodiment of the present disclosure.

FIG. 34 is a schematic diagram of a cross-sectional structure of a laser module in one or more other embodiments according to yet another embodiment of the present disclosure.

FIG. 35 is a schematic diagram of a cross-sectional structure of a laser module in one or more other embodiments according to yet another embodiment of the present disclosure.

FIG. 36 is a schematic diagram of a cross-sectional structure of a laser module in one or more other embodiments according to yet another embodiment of the present disclosure.

FIG. 37 is a schematic diagram of a plan structure of a base plate in one or more other embodiments according to yet another embodiment of the present disclosure.

FIG. 38 is a schematic diagram of a cross-sectional structure of a laser module in one or more other embodiments according to yet another embodiment of the present disclosure.

FIG. 39 is a schematic diagram of a cross-sectional structure of a laser module in one or more other embodiments according to yet another embodiment of the present disclosure.

FIG. 40 is a schematic diagram of a cross-sectional structure of a laser module in one or more other embodiments according to yet another embodiment of the present disclosure.

FIG. 41 is a schematic diagram of a cross-sectional structure of a laser module in one or more other embodiments according to yet another embodiment of the present disclosure.

FIG. 42 is a schematic diagram of a plan structure of a laser module in one or more other embodiments according to yet another embodiment of the present disclosure.

FIG. 43 is a schematic diagram of a cross-sectional structure of a laser module in one or more other embodiments according to yet another embodiment of the present disclosure.

FIG. 44 is a schematic diagram of a plan structure of a laser in one or more embodiments according to yet another embodiment of the present disclosure.

FIG. 45 is a schematic diagram of a cross-sectional structure of a laser in one or more embodiments according to yet another embodiment of the present disclosure.

FIG. 46 is a schematic diagram of a plan structure of a laser module in one or more other embodiments according to yet another embodiment of the present disclosure.

FIG. 47 is a schematic diagram of a cross-sectional structure of a laser module in one or more other embodiments according to yet another embodiment of the present disclosure.

FIG. 48 is a schematic diagram of a 3D structure of a laser module in one or more other embodiments according to yet another embodiment of the present disclosure. and

FIG. 49 is a schematic diagram of a plan structure of a laser module in one or more other embodiments according to yet another embodiment of the present disclosure.

### DETAILED DESCRIPTION

To make the objectives, technical solutions, and advantages of the present disclosure clearer, the embodiments of the present application will be described in further detail below with reference to the accompanying drawings.

In recent years, miniaturization and portability of electronic devices have become a major trend. In the industry of display products, conventional LCD TVs are no longer the first choice for consumers due to their large size and heavy weight. Gradually, small-sized and lightweight display products such as micro projectors have become increasingly popular. Driven by the major trend, laser modules, as core components of the display products, are naturally also gradually evolving towards miniaturization.

A laser module mainly includes a laser and a base plate. The laser is connected to the base plate, and an electrical connection between the laser and the base plate is achieved through pins. The base plate is configured to provide a mounting foundation for the laser. The laser is configured to emit laser light and is a key functional component in the laser module. The laser is first described below.

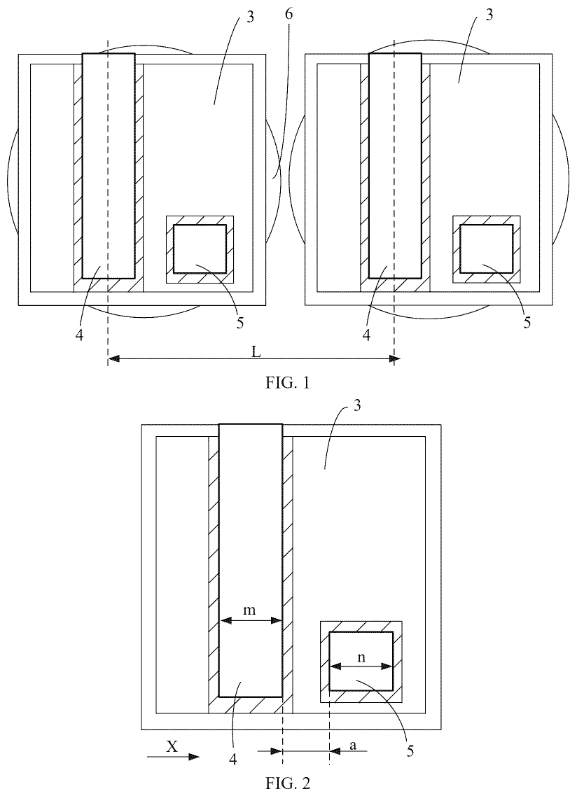

In the related art, as shown in FIG. 1 and FIG. 2, the laser includes a frame, a substrate, heat sinks, light-emitting chips 4, and protective devices 5. The frame and the heat sinks are both fixed to the substrate, and the heat sinks 3 are located inside the frame 1. The light-emitting chip 4 and the protective device 5 are located on the heat sink 3. The laser includes a plurality of heat sinks 3, and each heat sink 3 is provided with the light-emitting chip 4 and the protective device 5.

To achieve miniaturization during light emission, the same number of or even a greater number of light-emitting chips 4 and heat sinks 3 are required to be mounted in a smaller laser frame to achieve a dense arrangement of the light-emitting chips 4 in the frame 1, which means that a distance L between two adjacent light-emitting chips 4 is required to be shortened, leading to severe heat accumulation and hindering heat dissipation. As shown in FIG. 1, the distance L between two adjacent light-emitting chips 4 is affected by the width of the light-emitting chip 4, the width of the heat sink 3, and the overflow dimension of glue 6 used to mount the heat sink 3.

Currently, on the one hand, due to technical limitations, the size of the light-emitting chip 4 cannot be reduced temporarily. On the other hand, limited by device capabilities and reliability requirements, the overflow dimension of the glue 6 cannot be further reduced, which otherwise easily leads to detachment of the heat sink 3. Therefore, how to reduce the width of the heat sink 3 becomes the key to solving the problem of miniaturization of the laser.

In addition, due to a weak anti-static capability of the light-emitting chip 4, a protective device 5 is required to be placed on the heat sink 3 and connected in parallel with the light-emitting chip 4 to protect the light-emitting chip 4.

In the related art, as shown in FIG. 2, the protective device 5 is soldered onto the heat sink 3, and the light-emitting chip 4 and the protective device 5 are arranged side by side along a width direction X of the heat sink 3. Since the device has a certain error when the light-emitting chip 4 and the protective device 5 are placed, a certain safety distance a is required to be maintained between the light-emitting chip 4 and the protective device 5 to prevent collision between the light-emitting chip 4 and the protective device 5, which results in occupation of m+a+n in the width direction by the light-emitting chip 4 and the protective device 5, leading to a larger width of the heat sink 3. In this case, it is difficult to further reduce the size of the heat sink 3.

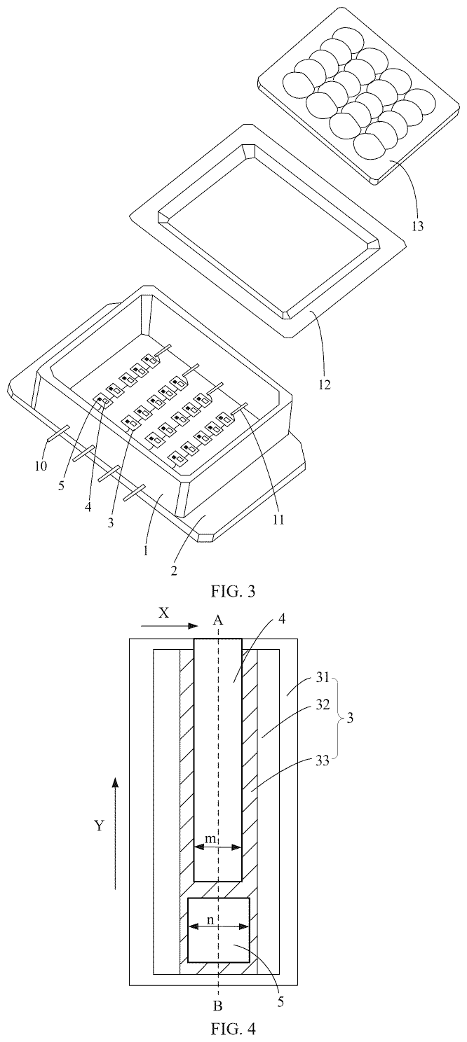

In view of the above technical problems, in an embodiment of the present disclosure, a laser is provided. As shown in FIG. 3 and FIG. 4, the laser includes a frame 1, a substrate 2, heat sinks, light-emitting chips 4, and protective devices 5. The frame 1 and the heat sinks 3 are both fixed to the substrate 1. The heat sinks 3, the light-emitting chips 4, and the protective devices 5 are all located inside the frame 1. The light-emitting chip 4 and the protective device 5 are fixed to the heat sink 3, and the light-emitting chip 4 and the corresponding protective device 5 have a spacing in a length direction Y of the heat sink 3.

An assembly formed by the heat sink 3, the light-emitting chip 4, and the corresponding protective device 5 can be called a chip on submount (COS).

The light-emitting chip 4 can also be referred to as a blue-green chip. The width of the light-emitting chip 4 may range from 0.1 mm to 0.3 mm. For example, the width of the light-emitting chip 4 is 0.2 mm. A light-emitting point of the light-emitting chip 4 is located at an end of the light-emitting chip 4 away from the protective device 5. The end at which the light-emitting point is located can be called a front end of the light-emitting chip 4, while an end close to the protective device 5 is called a rear end of the light-emitting chip 4. The light-emitting chip 4 may generate a lot of heat when operating, and the heat sink 3 is configured to absorb heat dissipated by the light-emitting chip 4.

The protective device 5 can also be referred to as a protective element. The protective device 5 may be a Zener diode or a voltage regulator tube. The width of the protective device 5 may range from 0.2 mm to 0.4 mm. For example, the width of the protective device 5 may be 0.3 mm. The protective device 5 is connected in parallel with the light-emitting chip 4 to improve the anti-static capability of the light-emitting chip 4.

According to the laser provided in the embodiments of the present disclosure, by setting a spacing between the light-emitting chip 4 and the protective device 5 in the length direction of the heat sink 3, no safety distance in the width direction is required between the light-emitting chip 4 and the protective device 5. Therefore, a dimension occupied by the light-emitting chip 4 and the protective device 5 in the width direction can be reduced, resulting in a narrower width of the laser and facilitating miniaturization of the laser.

In addition, it should be noted that the frame 1 of the laser is long and the distance between two adjacent heat sinks 3 in the length direction of the frame 1 is long. Consequently, even though the light-emitting chip 4 and the protective device 5 occupy a larger dimension in the length direction compared to the laser in the related art, the length of the frame 1 may not be increased, which will not adversely affect the miniaturization of the laser.

An arrangement of the light-emitting chip 4 and the protective device 5 will be exemplarily described below.

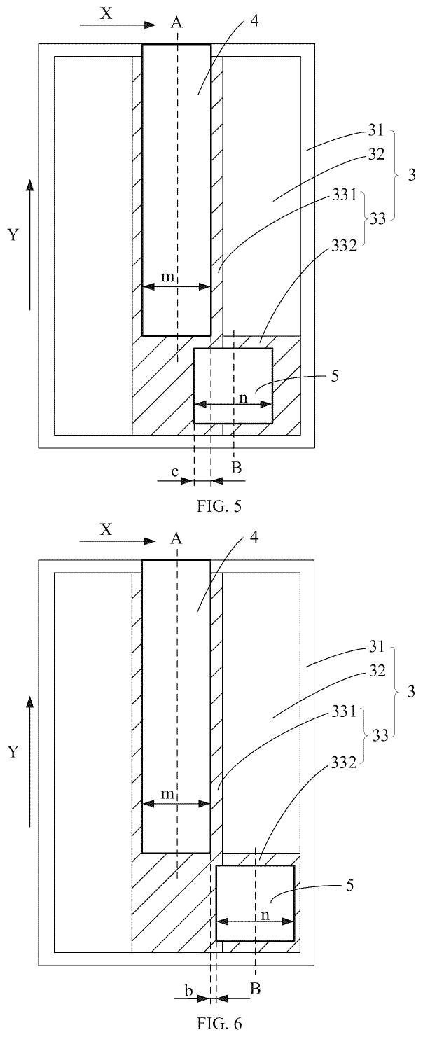

In some examples, as shown in FIG. 4 and FIG. 5, projections of the light-emitting chip 4 and the protective device 5 in the length direction Y of the heat sink 3 at least partially overlap.

In some examples, as shown in FIG. 5, assuming that a length of an overlapping portion of the projections of the light-emitting chip 4 and the protective device 5 in the length direction Y of the heat sink 3 is c, the dimension occupied by the light-emitting chip 4 and the protective device 5 in the width direction X of the heat sink 3 is m+n−c.

c may alternatively be 0, in which case a side edge of the light-emitting chip 4 overlaps with a side edge of the protective device 5.

To further reduce the dimension occupied by the light-emitting chip 4 and the protective device 5 in the width direction X, in some examples, as shown in FIG. 4, the projection of the light-emitting chip 4 in the length direction Y of the heat sink 3 falls entirely within the projection of the protective device 5 in the length direction Y of the heat sink 3. The width m of the light-emitting chip 4 is less than the width n of the protective device 5.

In this way, the dimension occupied by the light-emitting chip 4 and the protective device 5 in the width direction X of the heat sink 3 is the width n of the protective device 5.

In some other examples, the projection of the protective device 5 in the length direction Y of the heat sink 3 may alternatively fall entirely within the projection of the light-emitting chip 4 in the length direction Y of the heat sink 3. The width m of the light-emitting chip 4 is greater than the width n of the protective device 5.

In this way, the dimension occupied by the light-emitting chip 4 and the protective device 5 in the width direction X of the heat sink 3 is the width m of the light-emitting chip 4.

For the above two situations, the dimension occupied by the light-emitting chip 4 and the protective device 5 in the width direction X can be minimized, thereby minimizing the width of the laser.

In some examples, as shown in FIG. 4, an axis of symmetry of the light-emitting chip 4 overlaps with that of the protective device 5.

In some examples, the distance between a first axis A of the light-emitting chip 4 and a second axis B of the protective device 5 in the width direction X of the heat sink 3 ranges from 0 to 0.35 mm.

According to actual measurement, when the distance between the first axis A and the second axis B ranges from 0 to 0.35 mm, the dimension occupied by the light-emitting chip 4 and the protective device 5 in the width direction X of the heat sink 3 is less than that occupied in the existing solution.

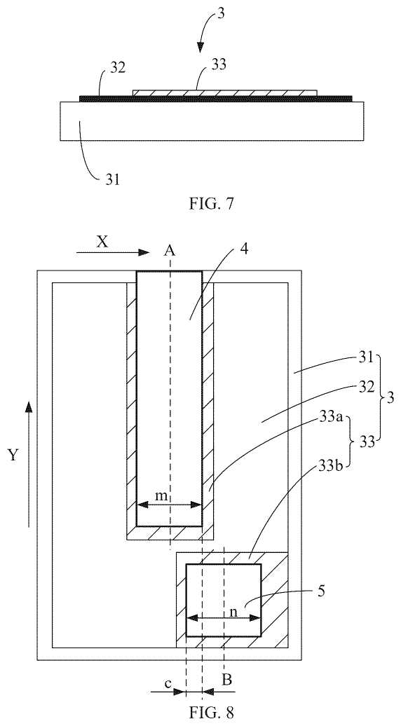

In some other examples, as shown in FIG. 6, the projections of the light-emitting chip 4 and the protective device 5 in the length direction Y of the heat sink 3 may not overlap. For example, the spacing in the width direction is b.

In this case, since no safe distance in the width direction X is required between the light-emitting chip 4 and the protective device 5, b can be less than the safe distance a in the related art, so that the purpose of reducing the width of the heat sink 3 can still be achieved. The minimum value of b may be 0.

In some examples, as shown in FIG. 7, the heat sink 3 includes a heat sink substrate 31, a gold layer 32, and a gold-tin layer 33 arranged in sequence. The width of the gold-tin layer 33 is less than that of the gold layer 32, and the width of the gold layer 32 is less than that of the heat sink substrate 31. The light-emitting chip 4 and the protective device 5 are soldered onto the gold-tin layer 33.

The structure of the gold-tin layer 33 is related to the arrangement of the light-emitting chip 4 and the protective device 5. An implementation of the gold-tin layer 33 will be illustrated below with reference to the arrangement of the light-emitting chip 4 and the protective device 5.

In some examples, as shown in FIG. 4 and FIG. 5, the gold-tin layer 33 is a monolithic gold-tin layer, that is, the light-emitting chip 4 and the corresponding protective device 5 are located on the same gold-tin layer 33.

In this case, when the light-emitting chip 4 and the protective device 5 are soldered onto the heat sink 3, the light-emitting chip 4 and the protective device 5 can both be soldered onto the gold-tin layer 33 only through a single eutectic bonding process on the gold-tin layer 33, thereby saving eutectic bonding time and improving manufacturing efficiency of the laser.

In some examples, as shown in FIG. 4, the gold-tin layer 33 is elongated and extends along the length direction Y of the heat sink 3, and the light-emitting chip 4 and the protective device 5 are arranged along the length direction of the gold-tin layer 33.

In some examples, as shown in FIG. 5, the gold-tin layer 33 is L-shaped, and includes a first region 331 and a second region 332. The first region 331 is elongated and extends along the length direction of the heat sink 3, and the second region 332 is located on one side of the first region 331. The light-emitting chip 4 is located in the first region 331, and the protective device 5 has one part located in the second region 332 and the other part located in the first region 331.

In the above implementation, the gold-tin layer 33 is designed in an L-shape. The light-emitting chip 4, the protective device 5, and the gold-tin layer 33 may be connected through pre-formed, integrated L-shaped gold-tin soldering, which can achieve simultaneous soldering of the light-emitting chip 4 and the protective device 5, thereby effectively improving soldering efficiency.

Certainly, to achieve the above integrated L-shaped gold-tin soldering, a safety distance is provided between the light-emitting chip 4 and the protective device 5 in both the width direction X and the length direction Y. In the width direction X, the distance between the first axis A of the light-emitting chip 4 and the second axis B of the protective device 5 is greater than half the sum of the width m of the light-emitting chip 4 and the width n of the protective device 5.

Through the arrangement of the positional relationship between the light-emitting chip 4 and the protective device 5, a dimension of the laser in the width direction is reduced, thereby facilitating the arrangement of a greater number of light-emitting chips 4 (within the same spatial range, the dimension of each packaged chip in the width direction becomes smaller, thereby leaving space for arrangement of more chips). In addition, during wire bonding, no obstruction or overlap may be formed, thereby enhancing the reliability of the wire bonding and reducing difficulty.

In the embodiment shown in FIG. 6, the gold-tin layer is L-shaped, and the gold-tin layer includes a first region 331 and a second region 332. The first region 331 is elongated and extends along the length direction of the heat sink 3. The second region 332 is located on one side of the first region 331, so that the first region 331 and the second region 332 form an integral L-shaped region. The light-emitting chip 4 is located in the first region 331, and the protective device 5 is located in the second region 332. In the examples, the light-emitting chip 4 and the protective device 5 are spaced apart in the length direction of the heat sink or the length direction of the light-emitting chip, and the light-emitting chip 4 and the protective device 5 are also spaced apart in the width direction of the heat sink or the width direction of the light-emitting chip. The term “spaced apart” means that there is a gap between edges of two devices close to each other.

Certainly, in some other examples, the gold-tin layer 33 may be in other shapes, as long as the above arrangement form of the light-emitting chip 4 and the protective device 5 can still be achieved, which is not limited in the embodiments of the present disclosure.

In some other examples, as shown in FIG. 8, the gold-tin layer 33 includes a first gold-tin layer 33a and a second gold-tin layer 33b that are separated from each other. The first gold-tin layer 33a and the second gold-tin layer 33b have a spacing in the length direction Y of the heat sink 3. The light-emitting chip 4 is located in the first gold-tin layer 33a, and the protective device 5 is located in the second gold-tin layer 33b.

Projections of the first gold-tin layer 33a and the second gold-tin layer 33b in the length direction Y of the heat sink 3 at least partially overlap.

In some examples, as shown in FIG. 8, the second gold-tin layer 33b is located on one side of the first gold-tin layer 33a, and the projections of the first gold-tin layer 33a and the second gold-tin layer 33b in the length direction Y of the heat sink 3 partially overlap.

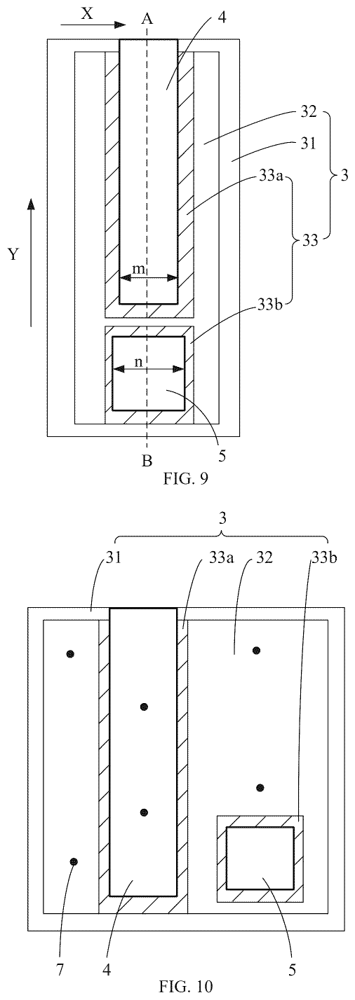

In some other examples, as shown in FIG. 9, the projections of the first gold-tin layer 33a and the second gold-tin layer 33b in the length direction Y of the heat sink 3 completely overlap. In this case, the first axis A of the light-emitting chip 4 and the second axis B of the protective device 5 may overlap.

After completion of the eutectic bonding of the light-emitting chip 4, the protective device 5, and the gold-tin layer 33, there is a need to perform an aging test on the laser. When the aging test is performed on the laser, the laser is required to be placed on a heat-dissipating base plate, and the gold layer 32, the light-emitting chip 4, and the heat-dissipating base plate are connected by using an electrical probe 7. After completion of the aging test, the electrical probes 7 are removed from the gold layer 32 and the light-emitting chip 4.

In the related art, as shown in FIG. 10 where the second gold-tin layer 33b is located on the right side of the first gold-tin layer 33a, since there is a spacing between the first gold-tin layer 33a where the light-emitting chip 4 is located and the second gold-tin layer 33b where the protective device 5 is located, an area of the gold layer 32 on the right side of the first gold-tin layer 33a may be larger than that of the gold layer 32 on the left side of the first gold-tin layer 33a, and at the same time, the position of the light-emitting chip 4 may shift to the left relative to an axis of the heat sink 3, resulting in uneven distribution of the electrical probe 7 relative to the light-emitting chip 4.

In this way, since the electrical probe 7 will be inserted and connected to the gold layer 32, a tensile force may be exerted on the gold layer 32, resulting in uneven force distribution between the gold layer 32 on the left side of the light-emitting chip 4 and the gold layer 32 on the right side of the light-emitting chip 4. Since the light-emitting chip 4 is soldered onto the first gold-tin layer 33a on the gold layer 32, uneven stress distribution on the gold layer 32 may also lead to an uneven tensile force on the light-emitting chip 4, so that the tensile force on the left side of the light-emitting chip 4 is greater than that on the right side of the light-emitting chip 4, thereby increasing the risk of damage to the light-emitting chip 4.

In addition, since the laser is wide, a region of the gold layer 32 not connected to the electrical probe 7 may not make sufficient contact with the heat-dissipating base plate. Particularly, the gold layer 32 on the right side of the light-emitting chip 4 is difficult to make sufficient contact with the heat-dissipating base plate, thereby affecting the heat dissipation effect on the laser and making the laser prone to damage.

In the laser provided in the embodiments of the present disclosure, projections of the light-emitting chip 4 and the protective device 5 in the length direction Y of the heat sink 3 at least partially overlap. Therefore, a region occupied by the gold-tin layer 33 is relatively narrow, which can reduce the difference in tensile forces on two sides of the light-emitting chip 4.

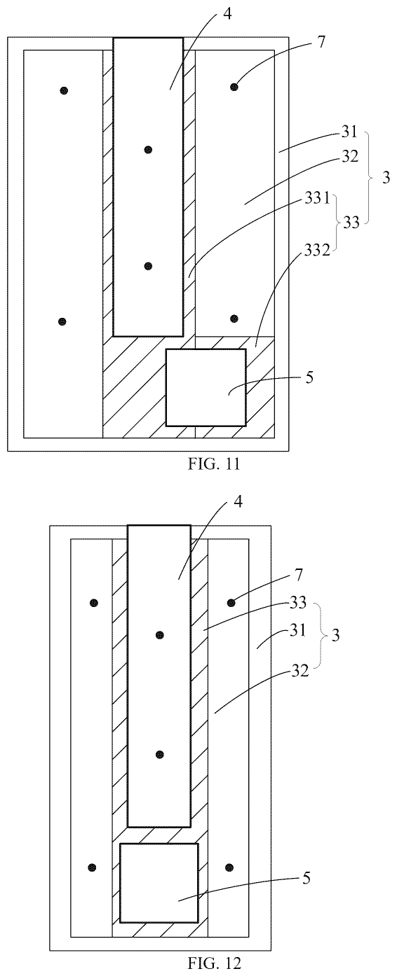

In some examples, as shown in FIG. 11 and FIG. 12, the widths of the gold layers 32 on two sides of the gold-tin layer 33 are equal.

In this way, when the aging test is performed on the laser, the electrical probes 7 can be distributed more uniformly on the gold layers 32 on two sides of the light-emitting chip 4, so that the stress on the gold layer 32 is more uniform, thereby causing tensile forces on the two sides of the light-emitting chip 4 to be more uniform and the light-emitting chip 4 to be less prone to damage.

At the same time, since the width of the gold-tin layer 33 is relatively small, that is, the width of the heat sink 3 is relatively small, the heat sink 3 can make sufficient contact with the heat-dissipating base plate, thereby helping heat dissipation of the laser.

In some examples, the widths of the gold layers 32 on the two sides of the light-emitting chip 4 may both range from 0.2 mm to 0.4 mm.

For example, the widths of the gold layers 32 on the two sides of the gold-tin layer 33 may both be 0.2 mm.

It is to be noted that the width of the gold layer 32 cannot be excessively small. The widths of the gold layers 32 on the two sides of the gold-tin layer 33 should be at least greater than the width of the electrical probe 7 to ensure that the electrical probe 7 can be connected to the gold layers 32.

Also, if the width of the gold layer 32 is excessively small, the heat dissipation effect of the heat sink 3 may be affected, which is not conducive to heat dissipation of the light-emitting chip 4, thereby making the light-emitting chip 4 prone to damage.

In some examples, as shown in FIG. 12, the lengths of the gold layers 32 on the two sides of the light-emitting chip 4 may also be the same.

In some examples, as shown in FIG. 3, the laser includes a plurality of heat sinks 3, a plurality of light-emitting chips 4, and a plurality of protective devices 5, and the numbers of the heat sinks 3, the light-emitting chips 4, and the protective devices 5 are equal. As shown in FIG. 14, the light-emitting chip 4 located on a first heat sink is connected to the gold layer 32 of a second heat sink through a gold wire 8, and the protective device 5 located on the second heat sink is connected to the gold layer 32 of the first heat sink through the gold wire 8. The first heat sink and the second heat sink are two adjacent heat sinks 3.

The heat sinks 3 are arranged in an array on the substrate 2, and the width direction of the heat sinks 3 is consistent with that of the substrate 2. Each row of heat sinks 3 is arranged along the width direction of the substrate 2, and the light-emitting chips 4 on each row of heat sinks 3 are connected in series.

Since the laser includes a plurality of uniformly arranged light-emitting chips 4 (heat sinks 3), after the laser is fabricated, adjacent light-emitting chips 4 (heat sinks 3) are required to be electrically connected to achieve a series connection between the adjacent light-emitting chips 4. Two adjacent light-emitting chips 4 are required to be electrically connected through the gold wire 8, and two ends of each gold wire 8 are soldered onto the heat sink 3, the light-emitting chip 4, or the protective device 5 through solder joints 9. After the two adjacent light-emitting chips 4 are electrically connected, the current flowing between the two light-emitting chips 4 is relatively large. The gold wire 8 has a relatively small diameter, and the maximum current that the gold wire 8 can withstand is thus small. Therefore, to prevent fusing of the gold wire 8 due to an excessively large circuit, three gold wires 8 may typically be used to electrically connect two adjacent light-emitting chips 4. In this way, the current passing through each gold wire 8 can be reduced, thereby making the gold wire 8 less prone to fusing.

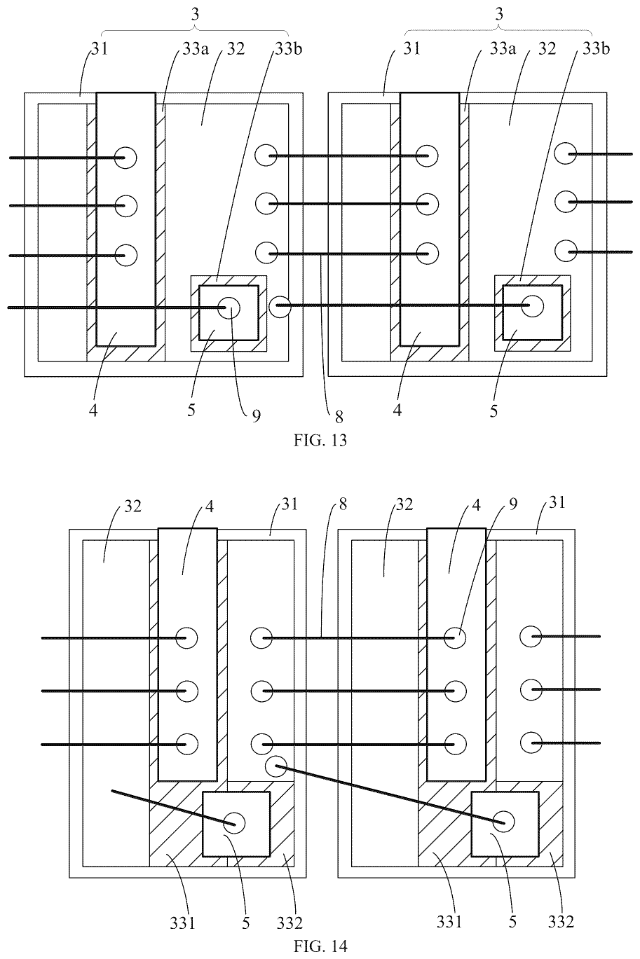

As shown in FIG. 13, in the related art, the light-emitting chip 4 is electrically connected to the gold layer 32 on the adjacent heat sink 3 through three gold wires 8. Since both the gold layer 32 and the first gold-tin layer 33a are metal layers, the gold layer 32 and the first gold-tin layer 33a are conductive, so that the current flowing through the light-emitting chip 4 can pass sequentially through the first gold-tin layer 33a and the gold layer 32, and then through an adjacent light-emitting chip 4, thereby achieving a series connection between two adjacent light-emitting chips 4.

To improve the anti-static capability of the light-emitting chip 4, the light-emitting chip 4 is generally connected in parallel with the protective device 5. In the related art, the protective device 5 is provided with solder joints 9 and is electrically connected to the adjacent heat sink 3 to achieve a series connection of adjacent light-emitting chip assemblies with the same color, and is also electrically connected to the corresponding chip through the heat sink 3, thereby achieving parallel connection between the light-emitting chip 4 and the protective device 5. As can be seen from the above, a surface of the light-emitting chip 4 in the related art is provided with three solder joints 9. The solder joints 9 may also be referred to as solder balls.

In the laser provided in the embodiments of the present disclosure, since the arrangement of the light-emitting chip 4 and the protective device 5 is different from that in the related art, the electrical connection manner is also adjusted accordingly.

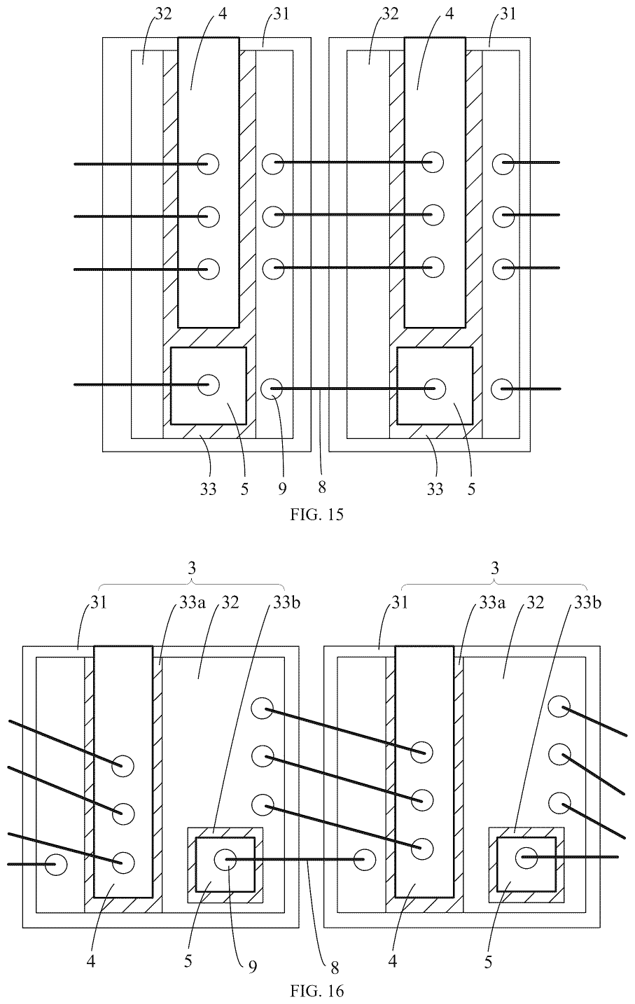

As shown in FIG. 14 and FIG. 15, the light-emitting chip 4 is electrically connected to the gold layer 32 of the adjacent heat sink 3 through three gold wires 8. Both the light-emitting chip 4 and the gold layer 32 are provided with corresponding solder joints 9. Since the gold layer 32 is not easily damaged by soldering, the protective device 5 is electrically connected to the gold layer 32 on the adjacent laser through a gold wire 8. The protective device 5 and the gold layer 32 are provided with corresponding solder joints 9.

As can be seen, the surface of the light-emitting chip 4 in the laser provided in the embodiments of the present disclosure is provided with three solder joints. The solder joints 9 on the light-emitting chip 4 and the solder joints 9 on the gold layer 32 are arranged uniformly or non-uniformly.

Both the gold layer 32 and the gold-tin layer 33 are made of conductive materials. Therefore, the light-emitting chip 4 is electrically connected to the gold layer 32 on the adjacent laser through the gold wire 8, thereby achieving an electrical connection between the light-emitting chip 4 and the light-emitting chip 4 on the adjacent laser and then achieving a series connection between the plurality of light-emitting chips 4. When the gold wires 8 are energized, one part of the current flows through the interior of the light-emitting chip 4, while the other part bypasses the surface of the light-emitting chip 4 and passes directly through the protective device 5, thereby achieving a parallel connection between the light-emitting chip 4 and the protective device 5 and then improving the anti-static capability of the light-emitting chip 4.

Compared with the related art, in the laser provided in the embodiments of the present disclosure, the surface of the light-emitting chip 4 is provided with fewer solder joints 9, which can reduce damage to the light-emitting chip 4 during the soldering.

In addition, after the number of the solder joints 9 on the surface of the light-emitting chip 4 is reduced, three solder joints 9 may be moved as a whole towards the rear end of the light-emitting chip 4, so that the solder joints 9 are away from the front end of the light-emitting chip 4, i.e., the solder joints 9 are away from a light-emitting point of the light-emitting chip 4, thereby reducing a risk of damage to the light-emitting point of the light-emitting chip 4 by the solder joints 9.

It is to be noted that, regarding the technical solution in the related art shown in FIG. 16, even if the gold wire 8 between the light-emitting chip 4 and the protective device 5 is also changed to the gold wire 8 between the protective device 5 and the gold layer 32, since the light-emitting chip 4 and the protective device 5 are arranged side by side, the gold wire 8 may hinder movement of the other three gold wires 8 towards the rear end of the light-emitting chip 4, so that the light-emitting point of the light-emitting chip 4 may still be significantly affected by the solder joint 9. If only the solder joints 9 on the light-emitting chip 4 are moved towards the rear end of the light-emitting chip 4, the corresponding three gold wires 8 may tilt. The gold wire 8 close to the protective device 5 may cross and collide with the gold wire 8 between the protective device 5 and the gold layer 32. Therefore, in the related art, it is not feasible to simply move the solder joints 9 on the light-emitting chip 4 towards the rear end of the light-emitting chip 4.

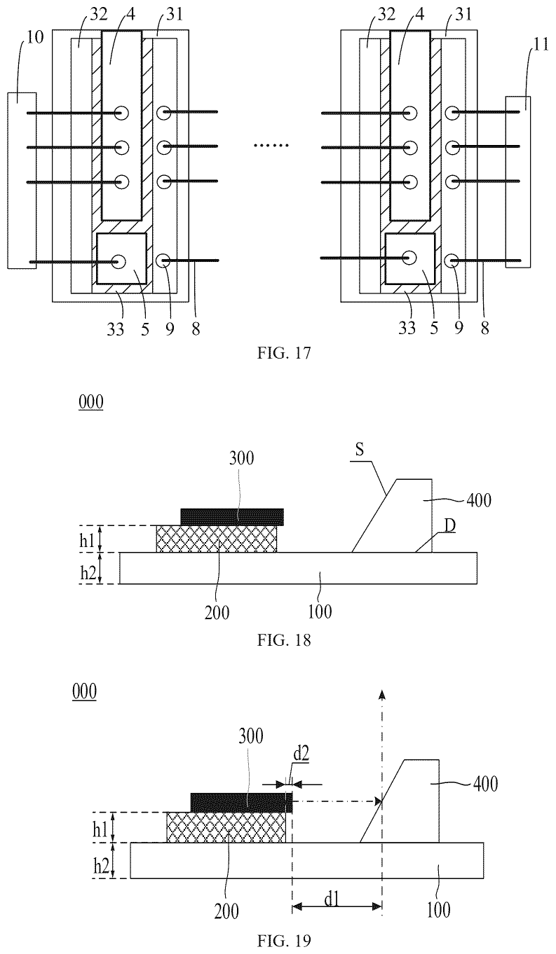

An assembly formed by the heat sink 3, the light-emitting chip 4, and the protective device 5 may be called a COS. As shown in FIG. 17, after a plurality of COSs are connected in series, two COSs located at two ends are electrically connected to a first electrical connector 10 and a second electrical connector 11, respectively. Both the first electrical connector 10 and the second electrical connector 11 are electrically connected to the substrate 2. The substrate 2 includes a driving circuit, and the driving circuit can send an electrical signal to the light-emitting chips 4 through the first electrical connector 10 or the second electrical connector 11, thereby driving the light-emitting chips 4 to emit laser light. The first electrical connector 10 and the second electrical connector 11 may be PINs.

Assuming that the driving circuit sends an electrical signal to the COS through the first electrical connector 10, one part of the current conducted through the first electrical connector 10 has one part flows through the light-emitting chip 4 and the other part flows through the protective device 5, and then the two parts converge onto the gold layer 32. The current on the gold layer 32 then enters the next COS, with one part flowing through the light-emitting chip 4 and the other part flowing through the protective device 5. The current finally flows through the second electrical connector 11.

In some examples, 16 to 36 heat sinks 3 (COSs) may be provided.

For example, 20 heat sinks 3 (COSs) may be provided, and the plurality of heat sinks 3 (COSs) may be uniformly distributed in four rows and five columns. The COSs in each row are connected in series, and the COSs at two ends of each row of COSs are electrically connected to the first electrical connector 10 and the second electrical connector 11, respectively.

In some examples, as shown in FIG. 3, the laser further includes a cover plate 12 and a lens assembly 13, and the frame 1, the cover plate 12, and the lens assembly 13 are arranged in sequence. The lens assembly 13 includes a plurality of lenses, and the number of the lenses is the same as that of the light-emitting chips 4. The lenses are configured to converge the laser light emitted by the light-emitting chips 4.

In another embodiment of the present disclosure, a laser is provided. Referring to FIG. 18, FIG. 18 is a side view of a laser according to embodiments of the present disclosure. The laser 000 may include a substrate 100, at least one heat sink 200, and at least one light-emitting chip 300.

The at least one heat sink 200 in the laser 000 may be located on one side of the substrate 100, and each heat sink 200 is fixedly connected to the substrate 100.

The at least one light-emitting chip 300 in the laser 000 may be in one-to-one correspondence with the at least one heat sink 200. Each light-emitting chip 300 may be located on a side of the corresponding heat sink 200 facing away from the substrate 100, and each light-emitting chip 300 may be fixedly connected to the corresponding heat sink 200.

It is to be noted that the heat sink 200 in the laser 000 refers to a heat sink made of diamond, and the substrate 100 in the laser 000 refers to a base plate made of a composite material of diamond and copper, i.e., the substrate 100 is made of diamond copper.

It is to be further noted that diamond has a relatively high heat conductivity coefficient, and has a relatively high heat conduction capability. Herein, the heat conduction capability of a material may be reflected by a heat conductivity coefficient. A relatively high heat conductivity coefficient indicates a relatively high heat conduction capability of the material. The unit of the heat conductivity coefficient is Watt per meter-Kelvin, which may also be expressed as W/(m·K). The heat conductivity coefficient of diamond is as high as 2000 W/(m·K). Therefore, a heat sink made of diamond (i.e., the heat sink 200) has a relatively high heat conductivity coefficient. In this way, during the operation of the laser 000, heat generated by the light-emitting chip 300 may be quickly conducted through the heat sink 200 along a direction perpendicular to the substrate 100, and may be conducted to the substrate 100. Moreover, the composite material of diamond and copper also has a high heat conductivity coefficient, so the heat conducted to the substrate 100 can quickly spread, and the substrate 100 can conduct the heat to the outside for heat dissipation. In this way, when the laser 000 is operating, the heat emitted by the light-emitting chip 300 in the laser 000 can be dissipated quickly, which results in a lower operating temperature of the light-emitting chip 300, leads to a better light emission effect of the light-emitting chip 300, and can also ensure that the light-emitting chip 300 is not easily damaged due to an excessively high temperature, thereby guaranteeing high reliability of the laser 000.

In some embodiments, as shown in FIG. 18, the laser 000 may further include at least one reflecting prism 400 located on one side of the substrate 100. Each reflecting prism 400 in the laser 000 may be fixedly connected to the substrate 100, and at least one reflecting prism 400 may be in one-to-one correspondence with at least one light-emitting chip 300. A light-emitting surface of each light-emitting chip 300 may face a reflecting surface S of the corresponding reflecting prism 400.

A surface of the reflecting prism 400 facing the substrate 100 is a bottom surface D of the reflecting prism 400. The bottom surface D of the reflecting prism 400 may be fixed to the substrate 100, and the angle between the bottom surface D of the reflecting prism 400 and the reflecting surface S is acute.

In this case, referring to FIG. 19 which is a diagram of an optical path of laser light emitted from a light-emitting chip in a laser according to embodiments of the present disclosure, the laser light emitted from the light-emitting chip 300 in the laser 000 may be directed towards the reflecting surface S of the corresponding reflecting prism 400 and may be reflected by the reflecting surface S of the reflecting prism 400. Herein, the laser light reflected by the reflecting surface S of the reflecting prism 400 may be transmitted along a direction facing away from the substrate 100.

It is to be noted that a cross-section of the reflecting prism 400 perpendicular to the substrate 100 may be in the shape of a right trapezoid. That is, the reflecting prism 400 may be a prism with a cross-section in the shape of a right trapezoid. This can facilitate machining of the reflecting prism 400 and can also ensure low difficulty in fixing the reflecting prism 400 to the substrate 100.

In the present disclosure, the reflecting prism 400 in the laser 000 is directly fixed to the substrate 100, the light-emitting chip 300 in the laser 000 is required to be fixed to the substrate 100 through the heat sink 200, and the laser light emitted by the light-emitting chip 300 in the laser 000 is typically in a divergent state. Therefore, a thickness h1 of the heat sink 200 in the laser 000 may affect the light extraction efficiency of the light-emitting chip 300. Herein, in a direction of an optical axis of each light-emitting chip 300 in the laser 000, a distance d between the light-emitting chip 300 and the reflecting surface S of the reflecting prism 400 may also affect the light extraction efficiency of the light-emitting chip 300. The following embodiments are described based on an example in which, in the direction of the optical axis of each light-emitting chip 300 in the laser 000, a distance d1 between the light-emitting chip 300 and the reflecting surface S of the reflecting prism 400 ranges from 0.3 mm to 0.5 mm.

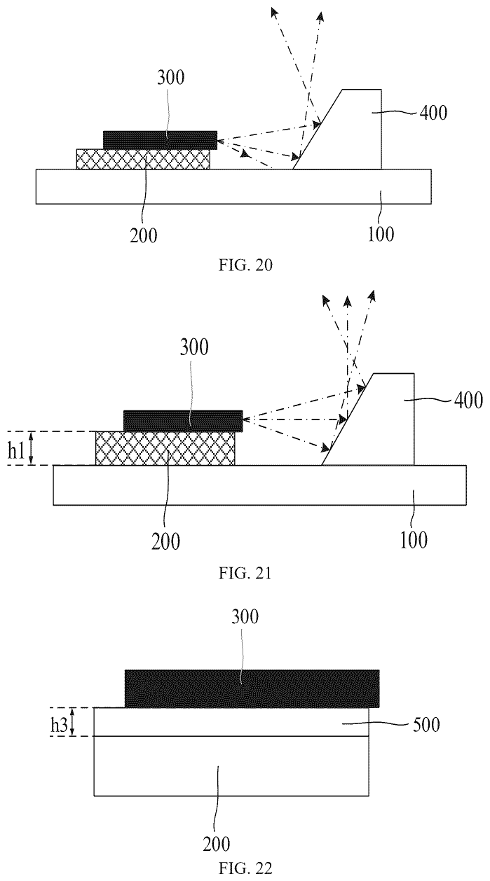

In this case, if the thickness h1 of the heat sink 200 is excessively small, for example, the thickness h1 of the heat sink 200 is less than 0.2 mm, referring to FIG. 20 which is a diagram of an optical path of laser light emitted from a light-emitting chip when a heat sink has a smaller thickness according to embodiments of the present disclosure, the laser light emitted from the light-emitting chip 300 in the laser 000 may not be completely directed towards the reflecting surface S of the reflecting prism 400. In the laser light emitted from the light-emitting chip 300, part of the laser light may be directly directed towards the substrate 100 and cannot be reflected by the reflecting surface S of the reflecting prism 400. As a result, the part of the laser light in the light-emitting chip 300 cannot be normally emitted from the laser 000, thereby leading to lower light extraction efficiency of the laser 000.

Therefore, the thickness h1 of the heat sink 200 in the embodiments of the present disclosure cannot be excessively small. For example, the thickness h1 of the heat sink 200 is required to be greater than or equal to 0.2 mm. In this case, as shown in FIG. 21 which is a diagram of an optical path of laser light emitted from another light-emitting chip according to embodiments of the present disclosure, when the thickness h1 of the heat sink 200 is greater than or equal to 0.2 mm, the laser light emitted from the light-emitting chip 300 in the laser 000 may be entirely directed towards the reflecting surface S of the reflecting prism 400, so that the reflecting surface S of the reflecting prism 400 can reflect all the laser light emitted from the light-emitting chip 300, and then most of the laser light emitted from the light-emitting chip 300 can be emitted from the laser 000, resulting in a relatively high light extraction efficiency of the laser 000.

In addition, if the thickness h1 of the heat sink 200 is excessively large, during the operation of the laser 000, the heat generated by the light-emitting chip 300 needs to pass through a long heat conduction path to be conducted to the substrate 100, resulting in lower efficiency of heat conduction from the light-emitting chip 300.

Therefore, the thickness h1 of the heat sink 200 in the embodiments of the present disclosure cannot be excessively large. Exemplarily, the thickness h1 of the heat sink 200 is required to be less than or equal to 0.4 mm. In this case, the heat sink 200 passes through a shorter heat conduction path when conducting the heat generated by the light-emitting chip 300 to the substrate 100, resulting in relatively high efficiency of heat conduction from the light-emitting chip 300 by the heat sink 200, which can further improve the heat dissipation efficiency of the light-emitting chip 300 through cooperation of the heat sink 200 and the substrate 100.

Therefore, in the embodiments of the present disclosure, the thickness h1 of the heat sink 200 ranges from 0.2 mm to 0.4 mm. Within the range of the thickness h1, the heat sink 200 can allow all the laser light emitted from the light-emitting chip 300 to be directed towards the reflecting surface S of the reflecting prism 400, resulting in a relatively high light extraction efficiency of the laser 000 and a relatively high efficiency of heat conduction from the light-emitting chip 300 by the heat sink 200.

Based on the above, the laser provided in the embodiments of the present disclosure includes a substrate, at least one heat sink, and at least one light-emitting chip. The heat sink has a high heat conductivity coefficient. During the operation of the laser, heat generated by the light-emitting chip may be quickly conducted to the substrate through the heat sink. Moreover, the composite material of diamond and copper also has a relatively high heat conductivity coefficient, so the heat conducted to the substrate can quickly spread, and the substrate can conduct the heat to the outside for heat dissipation. In this way, when the laser is operating, the heat emitted by the light-emitting chip in the laser can be dissipated quickly, which results in a lower operating temperature of the light-emitting chip, leads to a better light emission effect of the light-emitting chip, and can also ensure that the light-emitting chip is not easily damaged due to an excessively high temperature, thereby guaranteeing a high reliability of the laser. In addition, the thickness of the heat sink ranges from 0.2 mm to 0.4 mm. Within the range of the thickness, the heat sink can allow all the laser light emitted by the light-emitting chip to be directed towards the reflecting surface of the reflecting prism, resulting in a relatively high light extraction efficiency of the laser and a relatively high efficiency of heat conduction from the light-emitting chip by the heat sink. The heat dissipation efficiency of the light-emitting chip can thus be further improved.

In the embodiments of the present disclosure, a laser beam emitted by the light-emitting chip 300 is a beam that diverges in a cone shape. Therefore, as shown in FIG. 19, an end portion of the light-emitting chip 300 facing the reflecting prism 400 is required to protrude beyond the heat sink 200 to ensure that the laser beam emitted by the light-emitting chip 300 may not be directed towards the heat sink 200, thereby improving efficiency with which the laser light emitted by the light-emitting chip 300 is directed towards the reflecting prism 400. Herein, in the direction of the optical axis of the light-emitting chip 300, a length d2 by which the light-emitting chip 300 protrudes relative to the heat sink 200 ranges from 5 μm to 10 μm. This can ensure that all the laser light emitted from the light-emitting chip 300 can be directed towards the reflecting prism 400, and can also guarantee a large contact area between the light-emitting chip 300 and the heat sink 200, to ensure a relatively high heat conduction efficiency of the heat sink 200 for the light-emitting chip 300.

In some embodiments, as shown in FIG. 18 and FIG. 19, the substrate 100 in the laser 000 is made of a composite material of diamond and copper, while diamond has high hardness. Therefore, compared with a base plate made of oxygen-free copper, the substrate 100 has relatively high hardness. In this way, the substrate 100 can achieve a good support effect on the light-emitting chip 300 without requiring a thickness h2 of the substrate 100 to be excessively large, which effectively shortens the heat conduction path of the substrate 100.

For example, the thickness h2 of the substrate 100 in the laser 000 ranges from 1 mm to 4 mm. In this way, after the heat sink 200 conducts the heat generated by the light-emitting chip 300 to the substrate 100, the substrate 100 can conduct, through a shorter heat conduction path, the heat to the outside for heat dissipation. In this way, the heat dissipation efficiency of heat dissipation for the light-emitting chip 300 through the cooperation of the heat sink 200 and the substrate 100 can be further improved.

In the embodiments of the present disclosure, the light-emitting chip 300 in the laser 000 may be fixed to the heat sink 200 through solder. For example, as shown in FIG. 22, FIG. 22 is a schematic diagram of a light-emitting chip fixed to a heat sink according to embodiments of the present disclosure. The laser 000 may further include a solder layer 500 located on a side of the heat sink 200 facing away from the substrate 100. The heat sink 200 may be fixedly connected to the corresponding light-emitting chip 300 through the solder layer 500. Herein, the solder layer 500 may solder the light-emitting chip 300 after melting, so that the light-emitting chip 300 can be fixed to the heat sink 200.

It is to be noted that a side of each heat sink 200 in the laser 000 facing away from the substrate 100 is provided with the solder layer 500, so that each light-emitting chip 300 can be fixed to the corresponding heat sink 200 through the solder layer 500 on the corresponding heat sink 200.

In some embodiments, the solder layer 500 may be made of a gold-tin alloy, with a content of gold ranging from 75% to 80%.

In the present disclosure, a light-emitting layer in the light-emitting chip 300 is required to be grown on a base. The base in the light-emitting chip 300 is typically made of gallium arsenide (GaAs) or gallium nitride (GaN), and the base in the light-emitting chip 300 is required to be fixed to the substrate 100 through the solder layer 500. Since there is a certain difference between the coefficient of thermal expansion of the material of the base in the light-emitting chip 300 and the coefficient of thermal expansion of the solder layer 500, the light-emitting chip 300 and the solder layer 500 expand to different degrees when heated. During the operation of the laser 000, if the operating temperature of the light-emitting chip 300 is high, the heat generated by the light-emitting chip 300 may cause a large difference between expansion and deformation of the light-emitting chip 300 and expansion and deformation of the solder layer 500, resulting in greater thermal stress between the light-emitting chip 300 and the solder layer 500. The thickness of the solder layer 500 may directly affect the operating temperature of the light-emitting chip 300, which may in turn affect the degree of thermal expansion of the light-emitting chip 300 and the solder layer 500 and ultimately affect the magnitude of the thermal stress generated between the light-emitting chip 300 and the solder layer 500. Therefore, by optimizing the thickness of the solder layer 500, the thermal stress generated between the light-emitting chip 300 and the solder layer 500 cannot be excessively large.

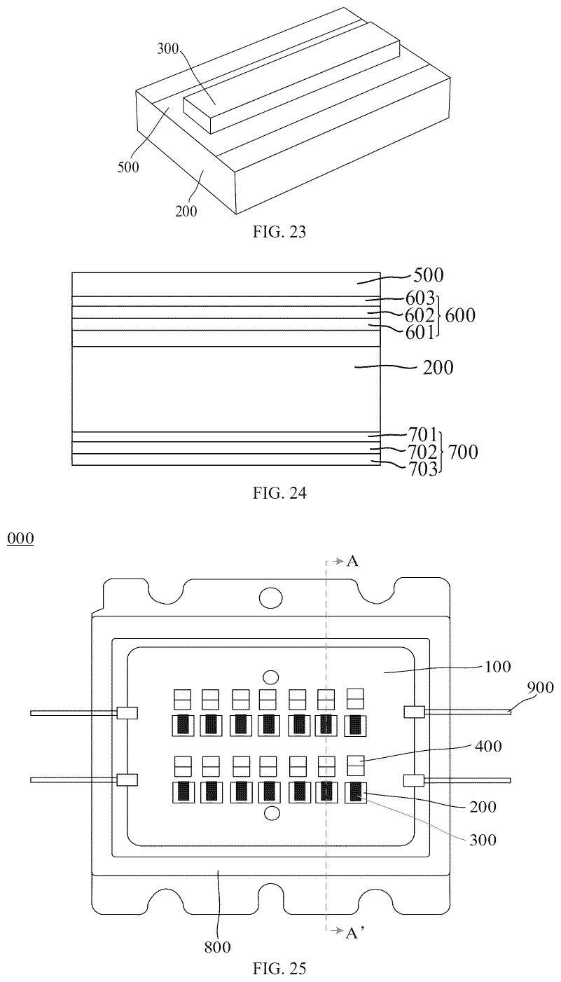

Exemplarily, as shown in FIG. 23 which is a schematic diagram of simulation of heat generation of a light-emitting chip according to embodiments of the present disclosure, it is assumed that, the thickness of the heat sink 200 is 0.28 mm, the light-emitting chip 300 has a length of 1.5 mm, a width of 0.3 mm, and a thickness of 0.1 mm, thermal power of the light-emitting chip 300 is 5 watts, and the light-emitting chip 300 is positioned centrally on the heat sink 200. Then, when the thickness of the solder layer 500 is 2 μm, the maximum operating temperature of the light-emitting chip 300 is 35.071° C., and the maximum thermal stress between the light-emitting chip 300 and the solder layer 500 is 6.285×10⁷ N/m² (newtons per square meter). When the thickness of the solder layer 500 is 4 μm, the maximum operating temperature of the light-emitting chip 300 is 35.448° C., and the maximum thermal stress between the light-emitting chip 300 and the solder layer 500 is 7.050×10⁷ N/m². When the thickness of the solder layer 500 is 6 μm, the maximum operating temperature of the light-emitting chip 300 is 35.822° C., and the maximum thermal stress between the light-emitting chip 300 and the solder layer 500 is 8.021×10⁷ N/m².

As can be seen, the solder layer 500 has a lower thermal conductivity. As the thickness of the solder layer 500 increases, the heat generated by the light-emitting chip 300 is difficult to dissipate promptly, resulting in a relatively high overall operating temperature of the light-emitting chip 300, which may in turn lead to a greater thermal stress between the light-emitting chip 300 and the solder layer 500. In addition, if the solder layer 500 is excessively thick, an adverse phenomenon of solder overflow may occur between the light-emitting chip 300 and the heat sink 200. If the thickness of the solder layer 500 is smaller, the overall operating temperature of the light-emitting chip 300 is lower, and the thermal stress between the light-emitting chip 300 and the solder layer 500 is smaller. However, if the thickness of the solder layer 500 is excessively small, the strength of soldering between the light-emitting chip 300 and the solder layer 500 may be lower, resulting in an adverse phenomenon of the formation of voids inside the solder layer 500, which in turn results in a lower strength of fixing between the light-emitting chip 300 and the heat sink 200.

Therefore, the solder layer 500 cannot be excessively thick, and the thickness of the solder layer 500 is required to be less than or equal to 5 μm. The solder layer 500 cannot be excessively thin, and the thickness of the solder layer 500 is required to be greater than or equal to 2 μm. That is, the thickness of the solder layer 500 ranges from 2 μm to 5 μm. This can ensure that the light-emitting chip 300 can be firmly fixed to the heat sink 200 through the solder layer 500, and can also ensure that the heat generated by the light-emitting chip 300 can be dissipated promptly through the heat sink 200, resulting in a lower overall operating temperature of the light-emitting chip 300 and then less thermal stress between the light-emitting chip 300 and the solder layer 500.

It is to be noted that FIG. 23 illustrates a heat generation pattern of the light-emitting chip, taking the light-emitting chip positioned centrally on the heat sink as an example. In actual products, the light-emitting end of the light-emitting chip is required to protrude beyond the heat sink.

In some embodiments, referring to FIG. 24 which is a schematic structural diagram of a heat sink according to embodiments of the present disclosure, the laser 000 may further include a first metal layer 600 located between the solder layer 500 and the heat sink 200, and a second metal layer 700 located between the heat sink 200 and the substrate 100.

Exemplarily, the first metal layer 600 in the laser 000 located between the solder layer 500 and the heat sink 200 may include a titanium layer 601, a platinum layer 602, and a gold layer 603 arranged in a stacked manner. The titanium layer 601 in the first metal layer 600 may be fixedly connected to a surface of the heat sink 200.

In this way, the gold layer 603 in the first metal layer 600 is a metal layer in the first metal layer 600 closest to the light-emitting chip 300, so that the gold layer 603 in the first metal layer 600 can serve as a conductive layer and be electrically connected to an electrode (which may be a positive electrode or a negative electrode) of the light-emitting chip 300. Herein, a solder layer 500 is further arranged between the gold layer 603 in the first metal layer 600 and the light-emitting chip 300, and the solder layer 500 is made of a gold-tin alloy. Therefore, the gold layer 603 in the first metal layer 600 may be connected to a power supply through a wire, to achieve the purpose of supplying, by the power supply, power to the light-emitting chip 300 through the gold layer 603 in the first metal layer 600 and the gold-tin alloy. Optionally, the gold layer 603 in the first metal layer 600 may also have a strong corrosion resistance, thereby enabling the gold layer 603 in the first metal layer 600 to protect the light-emitting chip 300 and prevent oxidation of the electrode of the light-emitting chip 300.

Both the platinum layer 602 and the titanium layer 601 in the first metal layer 600 can serve as adhesive layers to fix the gold layer 603 in the first metal layer 600 to the heat sink 200.

It is to be noted that it is difficult to directly plate the gold layer 603 onto the heat sink 200. Therefore, in the present disclosure, after the titanium layer 601 and the platinum layer 602 are first sequentially plated on the side of the heat sink 200 facing away from the substrate 100, the gold layer 603 is plated onto the platinum layer 602, thereby ensuring a secure arrangement of the gold layer 603 on the heat sink 200. In addition, both the titanium layer 601 and the platinum layer 602 in the first metal layer 600 have a relatively high thermal conductivity. Therefore, the heat generated by the light-emitting chip 300 can be effectively conducted to the heat sink 200 through the first metal layer 600.

In some embodiments, the thickness of the first metal layer 600 may be less than 1 μm to ensure that the first metal layer 600 can quickly conduct the heat generated by the light-emitting chip 300 to the heat sink 200 after the heat is conducted to the first metal layer 600.

The second metal layer 700 in the laser 000 may also include a titanium layer 701, a platinum layer 702, and a gold layer 703 arranged in a stacked manner. The titanium layer 701 in the second metal layer 700 may also be fixedly connected to the surface of the heat sink 200.

Herein, in the laser 000, each metal layer in the second metal layer 700 located between the heat sink 200 and the substrate 100 may serve as an adhesive layer to fix the heat sink 200 to the substrate 100.

It is to be noted that it is difficult to directly fix the heat sink 200 to the substrate 100. Therefore, in the present disclosure, the second metal layer 700 is required to be arranged on a side of the heat sink 200 close to the substrate 100, so that the heat sink 200 can be fixed to the substrate 100 through the second metal layer 700. Moreover, the gold layer 703 is less difficult to be fixed to the substrate 100 but is more difficult to be fixed to the heat sink 200, while the titanium layer 701 is less difficult to be fixed to the heat sink 200. The platinum layer 702 may serve as a transition layer between the gold layer 703 and the titanium layer 701, which can better bond with the gold layer 703 and the titanium layer 701. Therefore, when the titanium layer 701, the platinum layer 702, and the gold layer 703 in the second metal layer 700 are respectively plated on the side of the heat sink 200 close to the substrate 100, the difficulty of fixing the heat sink 200 to the substrate 100 can be reduced, and secure arrangement of the heat sink 200 on the substrate 100 can also be ensured.

In addition, the titanium layer 701, the platinum layer 702, and the gold layer 703 in the second metal layer 700 all have a relatively high thermal conductivity. Therefore, after the heat generated by the light-emitting chip 300 is conducted to the heat sink 200, the heat conducted to the heat sink 200 can be better conducted to the substrate 100 through the second metal layer 700.

In some embodiments, a thickness of the second metal layer 700 may be less than 1 μm to ensure that the second metal layer 700 can quickly conduct the heat conducted to the heat sink 200 to the substrate 10 after the heat is conducted to the second metal layer 700.

In the embodiments of the present disclosure, thicknesses of the titanium layer 601 in the first metal layer 600 and the titanium layer 701 in the second metal layer 700 may be equal, thicknesses of the platinum layer 602 in the first metal layer 600 and the platinum layer 702 in the second metal layer 700 may be equal, and thicknesses of the gold layer 603 in the first metal layer 600 and the gold layer 703 in the second metal layer 700 may be equal. Certainly, in other possible implementations, the thicknesses of the titanium layer 601 in the first metal layer 600 and the titanium layer 701 in the second metal layer 700 may be different, the thicknesses of the platinum layer 602 in the first metal layer 600 and the platinum layer 702 in the second metal layer 700 may be different, and the thicknesses of the gold layer 603 in the first metal layer 600 and the gold layer 703 in the second metal layer 700 may be different. This is not limited in the embodiments of the present disclosure.

Exemplarily, the thicknesses of the titanium layers in both the first metal layer 600 and the second metal layer 700 may range from 0.04 μm to 0.08 μm, the thicknesses of the platinum layers in both the first metal layer 600 and the second metal layer 700 may range from 0.1 μm to 0.3 μm, and the thicknesses of the gold layers in both the first metal layer 600 and the second metal layer 700 may range from 0.4 μm to 0.8 μm.

In the embodiments of the present disclosure, a gold layer may also be plated on the bottom surface D of the reflecting prism 400 in the laser 000, and the reflecting prism 400 may be fixed to the substrate 100 through the gold layer. Herein, since the gold layer plated on the bottom surface of the reflecting prism 400 has a better thermal conductivity, even if the laser light emitted from the light-emitting chip 3000 causes the temperature of the reflecting prism 400 to rise after irradiating the reflecting prism 400, it can be ensured that the reflecting prism 400 can quickly conduct the heat to the substrate 100 for heat dissipation through the gold layer arranged on the bottom surface D. Therefore, the substrate 100 may also provide heat dissipation for the reflecting prism 400, to ensure that the reflecting prism 400 may not expand or deform significantly due to an excessively high temperature, so that the laser light emitted from the light-emitting chip 300 can always irradiate the reflecting surface S of the reflecting prism 400, thereby guaranteeing a better light output effect of the laser 000.

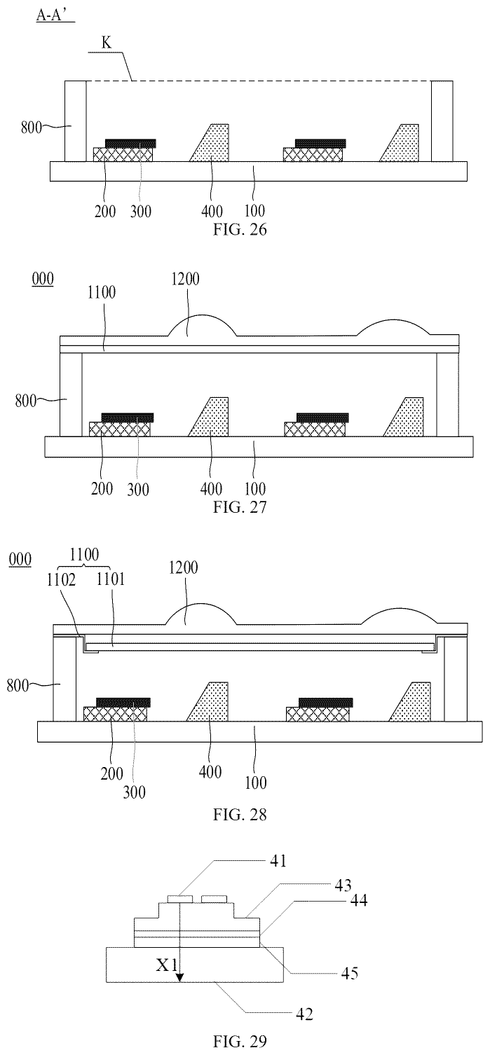

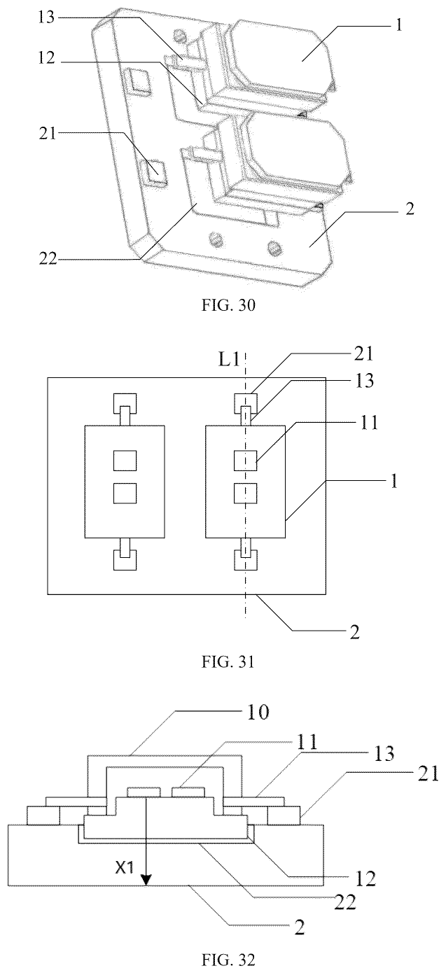

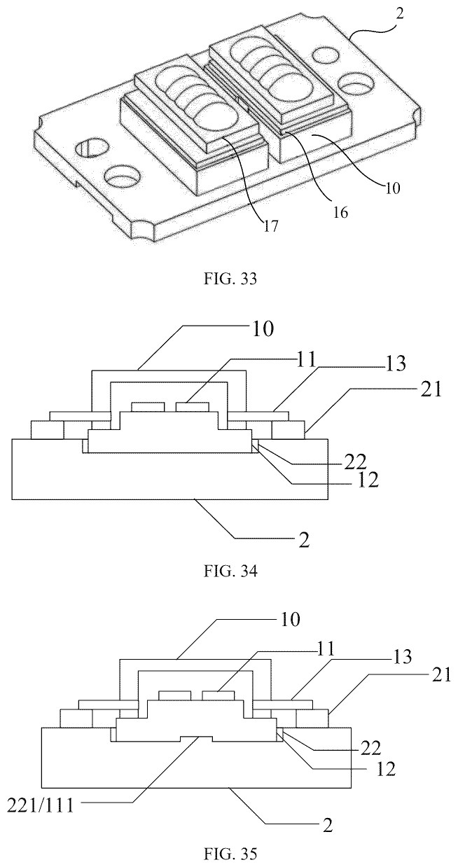

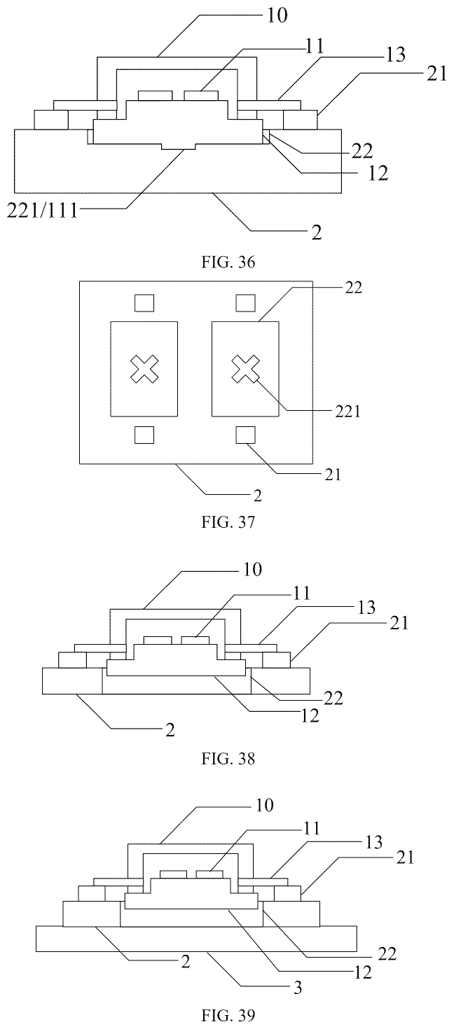

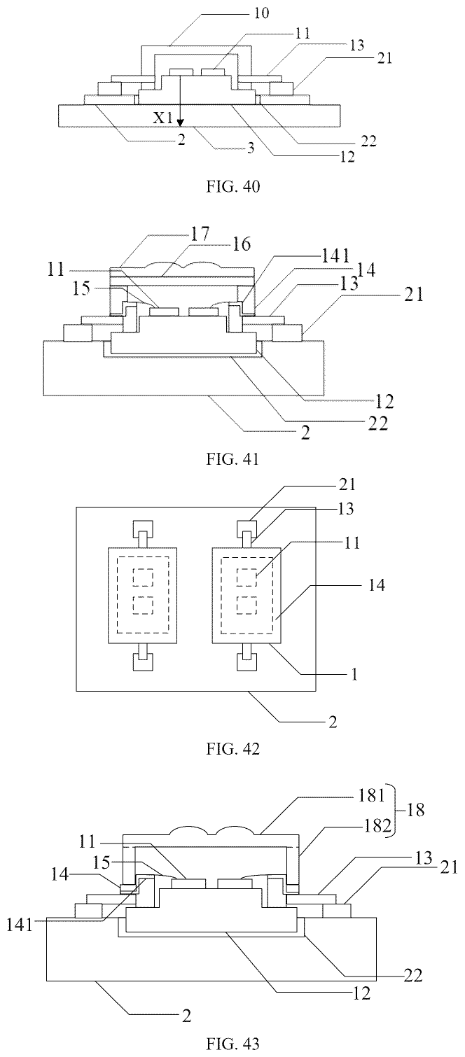

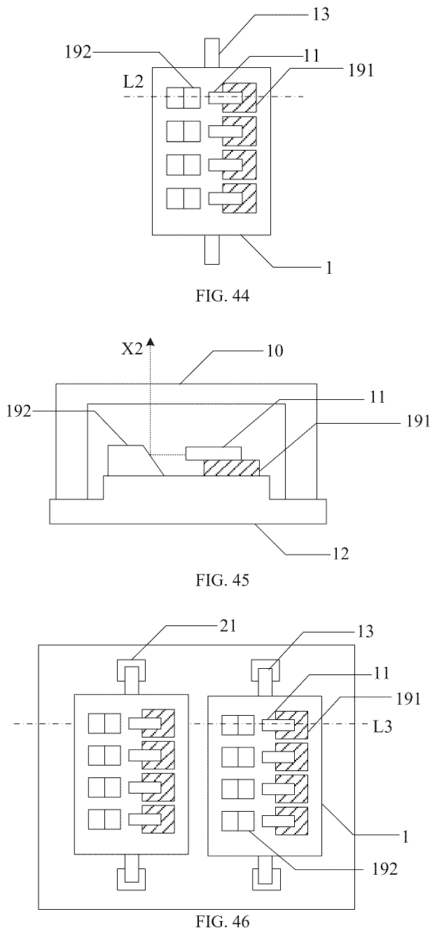

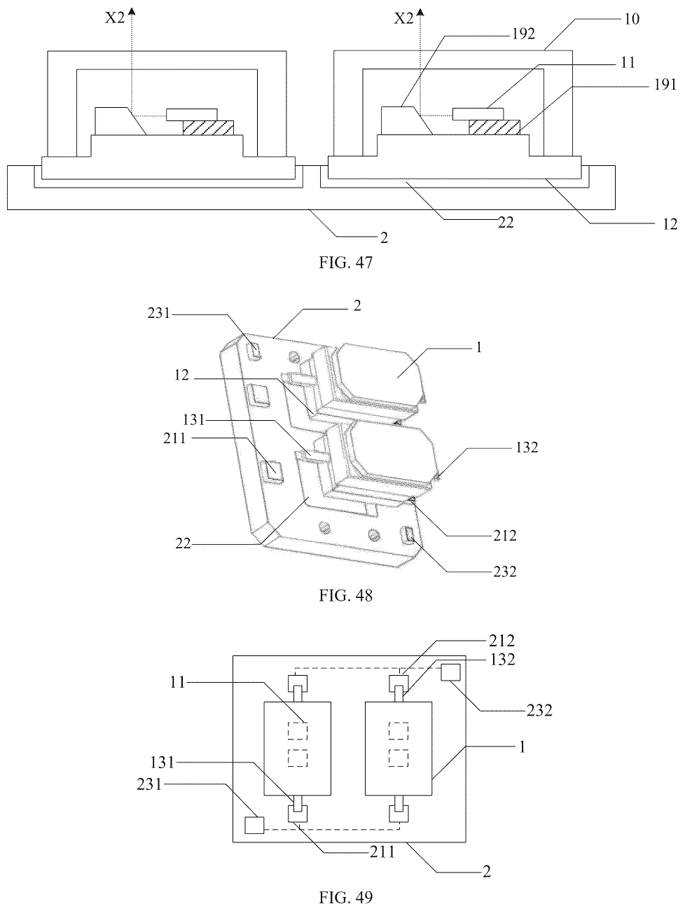

The above embodiments are all illustrated based on an example in which the laser includes a heat sink 200 and a light-emitting chip 300. When the laser 000 includes a plurality of diamond heat sinks 200 and a plurality of light-emitting chips 300, as shown in FIG. 25 which is a top view of another laser according to embodiments of the present disclosure, the plurality of heat sinks 200 in the laser 000 may be arranged in an array of multiple rows and columns, and each heat sink 200 has a corresponding light-emitting chip 300 fixed to the side facing away from the substrate 100. Herein, a plurality of reflecting prisms 400 may also be provided in the laser 000, each reflecting prism 400 may be fixed to the side of the substrate 100 facing the heat sink 200, and the plurality of reflecting prisms 400 may be in one-to-one correspondence with the plurality of light-emitting chips 300. Each reflecting prism 400 may be located on one side facing the light-emitting surface of the corresponding light-emitting chip 300, so that the reflecting surface of each reflecting prism 400 can reflect the laser light emitted from the corresponding light-emitting chip 300.

In the embodiments of the present disclosure, as shown in FIG. 25 and FIG. 26, out of which FIG. 26 is a cross-section view of the laser shown in FIG. 25 at A-A′, the laser 000 may further include a frame 800 fixedly connected to one side of the substrate 100. Each heat sink 200, each reflecting prism 400, and each frame 800 in the laser 000 may be fixed to the same side of the substrate 100, and each heat sink 200, each light-emitting chip 300, and each reflecting prism 400 in the laser 000 may be located in a region enclosed by the frame 800.

Herein, a structure formed by fixing the substrate 100 and the frame 800 in the laser 000 may be referred to as a package. Optionally, the frame 800 and the substrate 100 may be made of the same or different materials. For example, when the frame 800 is also made of a composite material of diamond and copper, the substrate 100 and the frame 800 may be an integrated structure. Certainly, the substrate 100 and the frame 800 may alternatively be two separate structures, and may be fixed together by soldering.

In some embodiments, as shown in FIG. 25, the laser 000 may further include a plurality of electrode pins 900 fixed to the frame 800. The electrode pin 900 may connect the interior and exterior of the region enclosed by the frame 800, and the electrode pin 900 may be electrically connected to the light-emitting chip 300 to deliver current to the light-emitting chip 300. Exemplarily, the electrode pin 900 may have a metal columnar structure. The frame 800 may have a plurality of mounting holes in one-to-one correspondence with the plurality of electrode pins 900. Each electrode pin 900 may be inserted into the corresponding mounting hole, and through a sealing material, the electrode pin 900 is fixed to the frame 800 and the mounting hole is filled and sealed, to ensure sealing of an accommodating space.

In the embodiments of the present disclosure, as shown in FIG. 26, the frame 800 in the laser 000 has a light-transmitting window K on the side facing away from the substrate 100. After the reflecting surface S of each reflecting prism 400 in the laser 000 reflects the laser light emitted from the corresponding light-emitting chip 300, the reflected laser light may then be directed towards the light-transmitting window K of the frame 800, so that the laser light can be emitted from the laser 000 through the light-transmitting window K.

In some embodiments, referring to FIG. 27 which is a schematic cross-sectional view of another laser according to embodiments of the present disclosure, the laser 000 may further include a light-transmitting sealing component 1100 located at the light-transmitting window K of the frame 800, and a collimating lens 1200 located on a side of the light-transmitting sealing component 1100 facing away from the substrate 100.

The light-transmitting sealing component 1100 may be fixed to the frame 800, to seal an accommodating space enclosed by the substrate 100 and the frame 800, thereby preventing damage to the light-emitting chip 300 from external moisture and other substances. The light-emitting chip 300 may emit laser light to the corresponding reflecting prism 50 under the current, and the reflecting prism 50 may reflect the received laser light back to the light-transmitting sealing component 1100. The laser light passes through the light-transmitting sealing component 1100 and is directed towards the collimating lens 1200, and the collimating lens 1200 may collimate the received laser light and then emit the laser light.

In some embodiments, the light-transmitting sealing component 1100 may be made of BK7 glass, sapphire, quartz, or the like. The collimating lens 1200 may be a freeform lens, an aspherical lens, or a Fresnel lens.

It is to be noted that the light-transmitting sealing component 1100 and the frame 800 may be connected in a variety of manners, which will be described in the embodiments of the present disclosure below using the following two cases as an example.

In the first case, as shown in FIG. 27, the light-transmitting sealing component 1100 may be fixed to the frame 800 by using a gold-tin solder or a sealing adhesive.

In the second case, as shown in FIG. 28, which is a schematic cross-sectional view of yet another laser according to embodiments of the present disclosure, the light-transmitting sealing component 1100 may alternatively be fixed to the frame 800 by parallel seam welding. The light-transmitting sealing component 1100 may include a light-transmitting sealing layer 1101 and a sealing frame 1102. The light-transmitting sealing layer 1101 is fixed to the sealing frame 1102, and the sealing frame 1102 may be fixed to the frame 800 by parallel seam welding.

Based on the above, the laser provided in the embodiments of the present disclosure includes a substrate, at least one heat sink, and at least one light-emitting chip. The heat sink has a relatively high heat conductivity coefficient. During the operation of the laser, heat generated by the light-emitting chip may be quickly conducted to the substrate through the heat sink. Moreover, the composite material of diamond and copper also has a relatively high heat conductivity coefficient, so the heat conducted to the substrate can quickly spread, and the substrate can conduct the heat to the outside for heat dissipation. In this way, when the laser is operating, the heat emitted by the light-emitting chip in the laser can be dissipated quickly, which results in a lower operating temperature of the light-emitting chip, leads to a better light emission effect of the light-emitting chip, and can also ensure that the light-emitting chip is not easily damaged due to an excessively high temperature, thereby guaranteeing a relatively high reliability of the laser. In addition, the thickness of the heat sink ranges from 0.2 mm to 0.4 mm. Within the range of the thickness, the heat sink can allow all the laser light emitted by the light-emitting chip to be directed towards the reflecting surface of the reflecting prism, leading to a relatively high light extraction efficiency of the laser, and can also ensure a relatively high efficiency of heat conduction from the light-emitting chip by the heat sink, which can further improve the heat dissipation efficiency of heat dissipation for the light-emitting chip.

The laser in the laser module is separately described above, and the laser module will be described below as a whole.

A cross-sectional structure of the laser module in the related art is shown in FIG. 29. The laser module includes a light-emitting chip 41, a module base plate 43, a circuit layer 44, a solder layer 45, and a module base plate 42. X1 denotes a heat dissipation path of the light-emitting chip. As can be seen, since the circuit layer 44 and the solder layer 45 are typically made of materials with poor thermal conductivity, the heat of the chip cannot be effectively dissipated through the heat dissipation path.

In view of the above technical problem, in yet another embodiment of the present disclosure, a laser module is provided. As shown in FIG. 30 to FIG. 32 (FIG. 30 is a 3D view of the laser module, FIG. 31 is a top view of a light emission direction of the laser module, and FIG. 32 is a cross-sectional view of the laser module in the embodiment in FIG. 31 taken along the dashed line L1, the laser module includes at least one laser 1 and a base plate 2.

The laser 1 includes a light-emitting chip 11, a substrate 12, and at least one pin 13. The light-emitting chip 11 is located on one side of the substrate 12. The pin 13 is located on at least one side surface of the laser 1 perpendicular to the plane where the substrate 12 is located, and is electrically connected to the light-emitting chip 11.

In some embodiments, both the base plate 2 and the substrate 12 are metal base plates, and the light-emitting chip 11 is soldered onto the substrate 12.

In some embodiments, the light-emitting chip 11 is a semiconductor light-emitting chip, including a light-emitting element. The light-emitting element receives an electrical signal from the outside through the pin 13 and emits laser light towards the outside, and the light emission direction is a direction away from the substrate 12.

In some embodiments, as shown in FIG. 32, the laser 1 further includes packaging frame bodies 10, and the packaging frame 10 and the substrate 12 jointly form a sealed space accommodating the light-emitting chip 11. Optionally, all the packaging frame bodies 10 may be in the shape of a square ring. An orthographic projection of each packaging frame 10 on the substrate 12 may be in the shape of a rectangle or roughly in the shape of a rectangle. For example, the orthographic projection may be in the shape of a rounded rectangle or a chamfered rectangle. The rounded rectangle is a shape obtained by replacing corners of a rectangle with rounded corners, while the chamfered rectangle is a shape obtained by replacing corners of a rectangle with chamfered corners.

The base plate 2 includes a soldering portion 21 and at least one groove 22 on one side. At least part of the substrate 12 of a laser 1 is disposed in one groove 22, and the pin 13 is soldered to the soldering portion 21.

In some embodiments, the groove 22 and the substrate 12 are dimensionally matched, and the length and the width of the groove 22 may be slightly greater than those of the substrate 12. Alternatively, after the substrate 12 is fitted into the groove 22, an outer sidewall of the substrate 12 may be in contact with an inner sidewall of the groove 22. The depth of the groove 22 may be correspondingly set according to different embodiments. In some embodiments, half of the thickness of the substrate 12 is located outside the groove 22.

In some embodiments, after the substrate 12 is fitted into the groove 22, the pin 13 may be in contact with the soldering portion 21 directly or through a solder. Optionally, the pin 13 and the soldering portion 21 may be soldered by lead-based soldering or tin-based soldering. Soldering manners not specifically mentioned in other embodiments of the present disclosure can be referred to here and may not be repeated.

In some embodiments, a control circuit is provided inside the base plate 2, and the soldering portion 21 is electrically connected to the control circuit inside the base plate 2, thereby forming an electrical connection loop including the control circuit, the soldering portion, the pin, and the light-emitting chip. The embodiments of the present disclosure focus on the packaging structure of the laser, and the structure of the control circuit therein is not limited.

In the embodiments of the present disclosure, through the arrangement of the groove, the laser can be fitted onto the base plate and then soldered to the base plate through the pins on two sides, which can achieve fixation and electrical connection between the laser and the base plate on the basis of eliminating the solder between the laser and the base plate. At the same time, the heat dissipation path X1 of the light-emitting chip includes only the base plate 2 and the substrate 12, which can improve the heat dissipation effect of the laser and ensure the luminous efficiency of the laser. Moreover, in the related art, typically, circuit traces of the light-emitting chip may be arranged at the bottom of the laser, which serves as an electrical connection while soldering the bottom to the base plate. However, the circuit traces may further hinder heat dissipation. In the embodiments of the present disclosure, the electrical connection loop is arranged on the side surface of the laser, and the laser can be secured to the base plate by soldering only a few points, which simplifies the internal circuit structure of the laser and the soldering process and further enhances the heat dissipation effect of the laser.

In some embodiments, the laser 1 does not include the pin, and the light-emitting chip 11 is directly electrically connected to the base plate 2. In this case, referring to FIG. 33, the packaging frame 10 is made of a ceramic material, and the base plate 2 is made of a copper material. The packaging frame 10 and the base plate 2 are sealed and soldered to form an accommodating cavity. The accommodating cavity is used to accommodate the light-emitting chip 11 and the protective device 5. An opening of the accommodating cavity facing away from the base plate 2 is sealed by sapphire sealing glass. An integrated collimating lens assembly is provided on the side of the sapphire sealed glass facing away from the base plate 2. Traces inside the accommodating cavity are connected to the gold wires of the light-emitting chip 11 and the protective device 5, and then are communicated with a conductive pattern region on the base plate 2.

It is to be noted that, in the embodiments of the present disclosure shown in FIG. 30 to FIG. 32, one laser module includes two lasers. However, in the implementation, one or more lasers may be provided, and the plurality of lasers may be arranged in sequence along a first direction. Those skilled in the art can implement the embodiments of the one or more lasers without creative efforts according to the content disclosed in the embodiments of the present disclosure, all of which fall within the protection scope of the present disclosure. The same applies to the other drawings in the present disclosure, and details are not described again.

The laser 1 in the embodiments of the present disclosure may be a monochromatic laser or a multicolor laser. The monochromatic laser is a laser that can emit laser light only in one color. The multicolor laser is a laser that can emit laser light in multiple colors. If the laser 1 is a monochromatic laser, different lasers 1 may be configured to emit laser light in different colors, or may be configured to emit laser light in the same color, which is not limited in the embodiments of the present disclosure.

Exemplarily, as shown in FIG. 31, the laser 1 may include a first laser and a second laser. The first laser may be the laser on the left side in FIG. 31, and the second laser may be the laser located on the right side in FIG. 31. The first laser may include a plurality of light-emitting chips. The second laser may also include a plurality of light-emitting chips. The plurality of light-emitting chips in the first laser may all be configured to emit red laser light. The plurality of light-emitting chips in the second laser may be configured partly to emit blue laser light and partly to emit green laser light. Exemplarily, the laser 1 may further include a first laser, a second laser, and a third laser arranged in sequence along the first direction. The first laser, the second laser, and the third laser may each include a plurality of light-emitting chips. The plurality of light-emitting chips in the first laser may all be configured to emit red laser light, the plurality of light-emitting chips in the second laser may all be configured to emit blue laser light, and the plurality of light-emitting chips in the third laser may all be configured to emit green laser light.

In some embodiments, slow axes of the laser light emitted by the plurality of light-emitting chips 11 in each laser 1 may all be parallel to an arrangement direction of the light-emitting chips 11. It is to be noted that propagation velocities of the laser light differ along different light vector directions. The light vector direction with a faster propagation velocity is a fast axis, while the light vector direction with a slower propagation velocity is a slow axis. The fast axis is perpendicular to the slow axis. The fast axis may be perpendicular to a surface of the light-emitting chip 11, and the slow axis may be parallel to the surface of the light-emitting chip 11. A divergence angle of the laser light on the fast axis is larger than that on the slow axis. For example, the divergence angle on the fast axis is basically more than 3 times that on the slow axis. The light-emitting chips 11 are arranged with the slow axis of the emitted laser light as the arrangement direction. Since the divergence angle of the laser light in the direction is smaller, the distance between the light-emitting chips 11 can be relatively small and the arrangement density of the light-emitting chips 11 can be relatively high on the basis of preventing interference and overlap of laser light emitted by adjacent light-emitting chips 11, which is conducive to miniaturization of the laser. Optionally, the plurality of light-emitting chips 11 in the laser may alternatively be arranged in an array including multiple rows and multiple columns, which is not limited in the embodiments of the present disclosure.

In some embodiments, each laser may be elongated, and an orthographic projection of each laser onto the substrate may be roughly in the shape of a rectangle. The width direction of the rectangle may be parallel to the first direction, and the length direction may be parallel to a second direction. Alternatively, the width direction of the rectangle may be parallel to the second direction, and the length direction may be parallel to the first direction.

It is to be noted that, in the present disclosure, in the embodiments shown in FIG. 30 to FIG. 32, one laser includes two light-emitting chips. However, in the implementations, each laser may include one or a plurality of light-emitting chips, and the plurality of light-emitting chips may be arranged in sequence along the second direction. Those skilled in the art can implement the embodiments, in which each laser includes one or a plurality of light-emitting chips, without creative efforts according to the content disclosed in the embodiments of the present disclosure, all of which fall within the protection scope of the present disclosure. The same applies to the other drawings in the present disclosure, and details are not described again. In some embodiments, the substrate 12 is an oxygen-free copper substrate.

The oxygen-free copper substrate has a relatively high heat conductivity coefficient, which can reach 400 W/mK, thereby achieving a better heat dissipation effect and further helping dissipate heat from the light-emitting chip module. Although oxygen-free copper is theoretically pure copper containing neither oxygen nor any deoxidizer residues, it actually still contains trace amounts of oxygen and some impurities. In the implementations, the content of oxygen is no more than 0.003%, the total content of the impurities is no more than 0.05%, and materials with copper purity greater than 99.95% can be used for the oxygen-free copper substrate.

In some embodiments, the above oxygen-free copper substrate further includes a nickel plating layer or a gold plating layer, which can improve the structural strength of soldered joints between the oxygen-free copper substrate and other components.

In some embodiments, as shown in FIG. 34, a side of the substrate 12 away from the light-emitting chip 11 is in contact with the bottom of the groove 22, which can increase the heat transfer area and further improve the heat dissipation effect.

In some embodiments, as shown in FIG. 35 or FIG. 36, when the side of the substrate 12 away from the light-emitting chip 11 is in contact with the bottom of the groove 22, the base plate 2 further includes a first fitting portion 221 at the bottom of the groove 22, and the substrate 12 includes a second fitting portion 111 on the side away from the light-emitting chip 11. The first fitting portion 221 and the second fitting portion 111 form a fitting structure. In the embodiments shown in FIG. 35, the first fitting portion 221 is a protrusion, and the second fitting portion 111 is a recess. In the embodiments shown in FIG. 36, the first fitting portion 221 is a recess, and the second fitting portion 111 is a protrusion.

Through the arrangement of the fitting portions, the laser 1 can be more tightly and firmly bonded to the base plate 2, ensuring the overall structural strength of the laser module.

In some embodiments, shapes of the first fitting portion 221 and the second fitting portion 111 are not limited. In some embodiments, by taking the base plate 1 shown in FIG. 37 as an example, the first fitting portion 221 is in the shape of X, and the shape of the second fitting portion 111 corresponds to that of the first fitting portion 221, which is also X. The first fitting portion 221 and the second fitting portion 111 are dimensionally matched. After the first fitting portion 221 and the second fitting portion 111 form the fitting structure, an outer sidewall/inner sidewall of the first fitting portion 221 is in contact with an outer sidewall/inner sidewall of the second fitting portion 111, and at the same time, the top/bottom of the first fitting portion 221 is in contact with the top/bottom of the second fitting portion 111.

In some embodiments, as shown in FIG. 38, the groove 22 passes through the base plate 2.

In the implementation, the entire laser module may be disposed on a heat-dissipating plate. As shown in FIG. 39, a side of the base plate 2 away from the laser 1 is in contact with an external heat-dissipating plate 3. Through the arrangement of the through groove 22, the manufacturing process of the base plate 2 can be simplified, and the heat dissipation effect of the laser can be improved through the external heat-dissipating plate.

In some embodiments, when the groove 22 passes through the base plate 2, to ensure the heat dissipation effect of the laser 1, the thickness of the base plate 2 is relatively small.

In some embodiments, as shown in FIG. 40, the substrate 12 is in contact with the heat-dissipating plate 3 through the groove 22 passing through the base plate 2, and the heat dissipation path X1 of the light-emitting chip 11 includes only the substrate 12 and the heat-dissipating plate 3, which further improves the heat dissipation effect of the laser.

In some embodiments, the packaging frame of the laser 1, as shown in FIG. 41 and FIG. 42, includes a frame 14. The frame 14 is connected to the substrate 12 and is located on the same side of the substrate 12 as the light-emitting chip 11. The frame 14 is arranged around four side surfaces of the light-emitting chip 11 that are perpendicular to the plane where the substrate 12 is located.

The frame 14 includes a metal conductive layer 141, and the light-emitting chip 11 and the pin 13 are both electrically connected to the metal conductive layer 141.

In the related art, typically, circuit traces of the light-emitting chip 11 may be arranged at the bottom of the laser, which serves as an electrical connection while soldering the bottom to the base plate in the substrate 12. However, the circuit traces may further hinder heat dissipation. In the embodiments of the present disclosure, an electrical connection path is arranged on the side surface of the laser, which has a simple structure, simplifies the internal circuit structure of the laser, and further enhances the heat dissipation effect of the laser.

In some embodiments, as shown in FIG. 41, the light-emitting chip 11 is electrically connected to the metal conductive layer 141 of the frame 14 inside the laser through leads 15, and the pin 13 is electrically connected to the metal conductive layer 141 of the frame 14 by soldering, thereby realizing the electrical connection path between the light-emitting chip 11 and the pin 13. The frame 14 may include the metal conductive layer 141 only in some regions, or the metal conductive layer 141 may be provided in all regions, which is not limited herein.

In some embodiments, the metal conductive layer 141 is a deposited tungsten paste layer.

In some embodiments, as shown in FIG. 41, the packaging frame of the laser may further include a glass cover plate 16 and a collimating lens 17. The glass cover plate 16 and the collimating lens 17 may be a sapphire cover plate and a sapphire lens, respectively. The collimating lens 17 has a divergence angle of less than 1° and a deflection angle of less than 0.8°, thereby achieving collimation of light emitted from the light-emitting chip 11.

In some embodiments, the frame 14 is soldered to the substrate 12 and the glass cover 16 by gold-tin soldering, to ensure air tightness of the packaging of the laser.

The glass cover 16 is located on a side of the frame 14 away from the substrate 12, and is configured to seal an opening on the side of the frame 14 away from the substrate 12, so as to form a sealed cavity together with the substrate 12 and the frame 14. Optionally, the laser 1 may not include the glass cover plate 16, and the collimating lens 17 is directly fixed to a surface of the frame 14 away from the substrate 12. In this way, the collimating lens 17 forms a sealed cavity together with the frame 14 and the substrate 12.

The collimating lens 17 is located on a side of the glass cover 16 away from the substrate 12. In the embodiments of the present disclosure, each collimating lens 17 may be integrally formed. Exemplarily, the collimating lens 17 is generally plate-shaped. A side of the collimating lens 17 close to the substrate 12 is planar, while a side away from the substrate 12 has one or more convex arc surfaces. Each of the convex arc surfaces forms a collimating microlens, and the collimating microlenses are in one-to-one correspondence with the plurality of light-emitting chips 11.

In some embodiments, as shown in FIG. 43, the packaging frame of the laser 1 further includes an integrated lens 18. The integrated lens 18 includes a lens portion 181 and a sidewall portion 182. The integrated lens 18 is connected to the frame 14. The lens portion 181 is located on a side of the light-emitting chip 11 away from the substrate 12, and the sidewall portion 182 is arranged around the four side surfaces of the light-emitting chip 11 that are perpendicular to the plane where the substrate 12 is located.

The integrated lens 18, together with the substrate 12 and the frame 14, forms a sealed cavity accommodating the light-emitting chip 11.

Compared with the embodiments shown in FIG. 41, the integrated lens 18 in the above embodiment can ensure air tightness of the packaging of the laser and can also reduce packaging procedures. The integrated lens 18 can be directly soldered to the frame 14, which reduces process difficulty and lowers manufacturing cost.

In some embodiments, a side of the lens portion 181 of the integrated lens 18 close to the substrate 12 is planar, while a side away from the substrate 12 has one or more convex arc surfaces. Each of the convex arc surfaces forms a collimating microlens, and the collimating microlenses are in one-to-one correspondence with the plurality of light-emitting chips 11.

In some embodiments, the integrated lens 18 is integrally formed during manufacturing. The division of the integrated lens 18 into the lens portion 181 and the sidewall portion 182 is only for clearly describing the structure of the integrated lens 18 and does not imply that the integrated lens 18 is formed by splicing multiple parts.

In some embodiments, the above integrated lens 18 is a sapphire integrated lens. The lens portion 181 has a divergence angle of less than 1° and a deflection angle of less than 0.8°, thereby achieving collimation of the light emitted from the light-emitting chip 11.

In some embodiments, the frame 14 is soldered to the integrated lens 18 by gold-tin soldering, to ensure air tightness of the packaging of the laser.

In some embodiments, to prevent stray light from passing through the sidewalls, the laser 1 further includes a light-absorbing film for absorbing stray light. The light-absorbing film is attached to four inner sidewalls of the integrated lens 18. The light-absorbing film is made of an opaque material, preferably an aluminum mold.

In some embodiments, the frame 14 includes an alumina frame. Alumina has high strength and chemical stability, has abundant raw material sources, and is suitable for manufacturing frames in different shapes. A connection surface between the alumina frame and the substrate 12 includes a metal coating. The metal coating is configured to improve the strength of soldering of the alumina frame to other components and thermal conductivity. In some embodiments, a connection surface between the alumina frame 14 and the glass cover plate 16 or the integrated lens 18 also includes a metal coating.

In some embodiments, as shown in FIG. 44 and FIG. 45 (FIG. 44 is a top view of a light emission direction of a laser, and FIG. 45 is a cross-sectional view of the laser according to the embodiment in FIG. 44 taken along the dashed line L2), each laser 1 may further include a heat sink 191 and a reflecting prism 192. The heat sinks 191 and the reflecting prisms 192 may both be in one-to-one correspondence with the plurality of light-emitting chips 11 in the laser module. Each light-emitting chip 11 is located on the corresponding heat sink 191, and the heat sink 191 is configured to assist in heat dissipation of the corresponding light-emitting chip 11. A material of the heat sink 191 may include ceramics. Each reflecting prism 192 is located on a light-emitting side of the corresponding light-emitting chip 11. The light-emitting chip 11 may emit laser light towards the corresponding reflecting prism 192, and the reflecting prism 192 may reflect the laser light towards the packaging frame 10 in a direction away from the substrate 12 (such as a direction X2). The packaging frame may include a glass cover plate 16 and a collimating lens 17, as shown in FIG. 41, or may include an integrated lens 18 as shown in FIG. 43. The reflecting prism 192 is configured to reflect, along a direction away from the substrate 12, the laser light towards the collimating lens 17 or the integrated lens 18 corresponding to the light-emitting chip 11, and then the laser light may be collimated by the lens and emitted.

In some embodiments, as shown in FIG. 46 and FIG. 47 (FIG. 46 is a top view of a light emission direction of a laser, and FIG. 47 is a cross-sectional view of the laser according to the embodiment in FIG. 46 taken along the dashed line L3), each laser 1 may include the heat sink 191 and the reflecting prism 192 in the above embodiments.

In some embodiments, as shown in FIG. 48 and FIG. 49, the laser module includes at least two lasers 1. Each laser 1 includes a positive pin 131 and a negative pin 132. The positive pin 131 is electrically connected to a positive electrode of the light-emitting chip 11, and the negative pin 132 is electrically connected to a negative electrode of the light-emitting chip 11.

The soldering portion 21 includes a positive soldering portion 211 and a negative soldering portion 212. The positive pin 131 is soldered to the positive soldering portion 211, and the negative pin 132 is soldered to the negative soldering portion 212.

In some embodiments, the positive soldering portions 211 are in one-to-one correspondence with the positive pins 131. Similarly, the negative soldering portions 212 are also in one-to-one correspondence with the negative pin 132. One laser module includes N lasers 1, that is, includes N positive soldering portions 211 and N negative soldering portions 212. Moreover, as shown in FIG. 48 and FIG. 49, the N positive soldering portions 211 are located on the same side, and the N negative soldering portions 212 are located on the other side.

The base plate 2 further includes a control circuit, a common positive electrode 231, and a common negative electrode 232. The control circuit is located inside the base plate 2. The common positive electrode 231 and the common negative electrode 232 are located on the same side of the substrate 12 and the soldering portion 21. The common positive electrode 231 is electrically connected to the control circuit and at least two positive soldering portions 211 inside the base plate 2 through a printed circuit, and the common negative electrode 232 is electrically connected to the control circuit and at least two negative soldering portions 212 inside the base plate 2 through a printed circuit.

Through the arrangement of the common positive electrode and the common negative electrode, an electrical connection loop including the control circuit, the common electrodes, the soldering portions, the pins, and the light-emitting chips is formed, which simplifies the wiring and the electrical connection manner of the laser module. The control circuit can control all the lasers in the laser module to emit light by providing electrical signals for the common negative electrode and the common positive electrode.

In some embodiments, when there are a small number of lasers in one laser module, for example, two, three, or four, as shown in the figures, the base plate 2 includes only one common positive electrode 231 and one common negative electrode 232. Moreover, the common positive electrode 231 is connected to all the positive soldering portions 211, and the common negative electrode 232 is connected to all the negative soldering portions 212, as shown in FIG. 49. If there is a larger number of lasers in one laser module, for example, eight, the base plate 2 may include two common positive electrodes 231 and two common negative electrodes 232. Each common positive electrode 231 is connected to four positive soldering portions 211, and each common negative electrode 232 is connected to four negative soldering portions 212. The same applies to embodiments of other numbers of lasers, which is not described in detail.

The common negative electrode 231 and the common positive electrode 232 shown in FIG. 48 and FIG. 49 are merely examples. In the implementation, the common negative electrode 231 and the common positive electrode 232 may be arranged inside the base plate 2, so that there are no obvious structural features on the outside of the base plate 2, which also falls within the protection scope of the present disclosure.

In some embodiments, the laser module may further include a plurality of power supply pins not shown in the accompanying drawings. The plurality of power supply pins are located on the base plate and may be located at the bottom or on a side surface of the base plate. The power supply pin is connected to the control circuit inside the base plate and is configured to connect to an external power supply, thereby establishing an electrical connection loop from the external power supply, the control circuit, the common electrodes, the pins, to the light-emitting chips, which in turn triggers each light-emitting chip to emit laser light. The plurality of power supply pins may include a plurality of positive power supply pins and at least one negative power supply pin. The positive power supply pin is configured for connection to a positive electrode of the external power supply, and the negative power supply pin is configured for connection to a negative electrode of the external power supply.

In the foregoing content, different embodiments of the laser module are described in detail in the present disclosure. It should be understood that the technical features involved in the embodiments (including, but not limited to, features in dimensions such as structural design, functional modules, connection relationships, and process parameters) can be freely and reasonably combined and used according to actual application requirements, provided that there are no contradictions, conflicts, or incompatibilities between the technical solutions. All such combinations fall within the scope of the present disclosure. In the present disclosure, the terms “at least one of A and B” and “A and/or B” are merely descriptions of an association between associated objects, indicating that three possible relationships may exist: A exists alone, A and B coexist, and B exists alone. The term “at least one of A, B, and C” indicates that seven relationships may exist, which may indicate: A exists alone, B exists alone, C exists alone, A and B coexist, A and C coexist, C and B coexist, and A, B, and C coexist. In the embodiments of the present disclosure, the terms “first” and “second” are used for descriptive purposes only and should not be construed as indicating or implying relative importance. The term “at least one” means one or more, and the term “a plurality of” means two or more, unless otherwise expressly defined.

The terms “comprising” and “including” used throughout the specification and claims are open-ended terms and should therefore be interpreted as “comprising/including, but not limited to”. “Roughly” means that, within an acceptable error range, those skilled in the art can solve the technical problem and basically achieve the technical effect within a certain error range. Certain terms are used throughout the specification and claims to refer to particular components. Those skilled in the art should understand that manufacturers may use different terms to refer to the same component. This specification and claims do not distinguish components by differences in name, but rather by differences in function.

The above descriptions are merely optional embodiments of the present disclosure and are not intended to limit the present disclosure. Any modifications, equivalent replacements, improvements, and the like made within the spirit and principles of the present disclosure should be included within the protection scope of the present disclosure.

What is claimed is:

1. A laser module, comprising a laser, wherein
the laser comprises a frame, a substrate, heat sinks, light-emitting chips, and protective devices;
the frame and the heat sinks are fixed to the substrate, and the heat sinks, the light-emitting chips, and the protective devices are located inside the frame; and
the light-emitting chips and the protective devices are fixed to the heat sinks, the light-emitting chip and the corresponding protective device have a spacing therebetween in a length direction of the heat sink, and orthographic projections of the light-emitting chip and the protective device in the length direction of the heat sink at least partially overlap or are spaced apart.

2. The laser module according to claim 1, wherein the heat sink comprises a gold-tin layer, a gold layer, and a heat sink substrate arranged in sequence from top to bottom;
a width of the gold-tin layer is less than that of the gold layer, and the width of the gold layer is less than that of the heat sink substrate; and
the light-emitting chip and the protective device each have a width smaller than that of the gold-tin layer, and the light-emitting chip and the protective device are soldered onto the gold-tin layer.

3. The laser module according to claim 1, wherein the heat sink comprises a gold-tin layer, a gold layer, and a heat sink substrate arranged in sequence from top to bottom, and the gold-tin layer is a monolithic gold-tin layer.

4. The laser module according to claim 3, wherein the gold-tin layer is elongated and extends along the length direction of the heat sink, and the light-emitting chip and the protective device are arranged along a length direction of the gold-tin layer; or
the gold-tin layer is L-shaped, the gold-tin layer comprises a first region and a second region, the first region is elongated and extends along the length direction of the heat sink, the second region is located on one side of the first region, the light-emitting chip is located in the first region, and the protective device has one part located in the second region and the other part located in the first region.

5. The laser module according to claim 3, wherein the gold-tin layer is L-shaped, the gold-tin layer comprises a first region and a second region, the first region is elongated and extends along the length direction of the heat sink, the second region is located on one side of the first region, the light-emitting chip is located in the first region, and the protective device is located in the second region.

6. The laser module according to claim 2, wherein the gold-tin layer comprises a first gold-tin layer and a second gold-tin layer that are separated from each other, the first gold-tin layer and the second gold-tin layer have a spacing therebetween in the length direction of the heat sink, and projections of the first gold-tin layer and the second gold-tin layer in the length direction of the heat sink at least partially overlap; and
the light-emitting chip is located in the first gold-tin layer, and the protective device is located in the second gold-tin layer.

7. The laser module according to claim 1, wherein the projections of the light-emitting chip and the protective device in the length direction of the heat sink partially overlap, the light-emitting chip has a first axis in the length direction of the heat sink, the protective device has a second axis in the length direction of the heat sink, and a distance between the first axis and the second axis is no greater than 0.35 mm.

8. The laser module according to claim 7, wherein the projection of the light-emitting chip in the length direction of the heat sink falls entirely within the projection of the protective device in the length direction of the heat sink; or
the projection of the protective device in the length direction of the heat sink falls entirely within the projection of the light-emitting chip in the length direction of the heat sink.

9. The laser module according to claim 1, wherein the substrate is made of diamond copper, the heat sink is made of diamond, and a thickness of the heat sink ranges from 0.2 mm to 0.4 mm.

10. The laser module according to claim 9, wherein the laser further comprises reflecting prisms located on one side of the substrate, each of the reflecting prisms is fixedly connected to the substrate, and the reflecting prisms are in one-to-one correspondence with the light-emitting chips, with a light-emitting surface of each of the light-emitting chips facing a reflecting surface of the corresponding reflecting prism;
in a direction of an optical axis of each of the light-emitting chips, a distance between the light-emitting chip and the reflecting surface of the corresponding reflecting prism ranges from 0.3 mm to 0.5 mm; and
an end portion of the light-emitting chip facing the reflecting prism protrudes beyond the heat sink, and in the direction of the optical axis of the light-emitting chip, a length by which the light-emitting chip protrudes relative to the heat sink ranges from 5 μm to 10 μm.

11. The laser module according to claim 9, wherein the laser further comprises a solder layer located on a side of the heat sink facing away from the substrate, and the heat sink is fixedly connected to the corresponding light-emitting chip through the solder layer.

12. The laser module according to claim 11, wherein the laser further comprises a first metal layer located between the solder layer and the heat sink and a second metal layer located between the heat sink and the substrate.

13. The laser module according to claim 12, wherein the first metal layer and the second metal layer each comprise a titanium layer, a platinum layer, and a gold layer arranged in a stacked manner, and the titanium layers in the first metal layer and the second metal layer are fixedly connected to a surface of the heat sink; and
wherein a thickness of the titanium layer ranges from 0.04 μm to 0.08 μm, a thickness of the platinum layer ranges from 0.1 μm to 0.3 μm, and a thickness of the gold layer ranges from 0.4 μm to 0.8 μm.

14. The laser module according to claim 1, further comprising a base plate,
wherein the laser further comprises pins, the light-emitting chip is located on one side of the substrate, and the pins are located on at least one side surface of the laser perpendicular to a plane where the substrate is located, and is electrically connected to the light-emitting chip, the base plate comprises a soldering portion and at least one groove on one side thereof, at least part of the substrate of one laser is located in one of the at least one groove, and the pins are soldered to the soldering portion; or
the light-emitting chip is directly electrically connected to the base plate.

15. The laser module according to claim 14, wherein a side of the substrate away from the light-emitting chip is in contact with a bottom of the groove.

16. The laser module according to claim 15, wherein the base plate further comprises a first fitting portion at the bottom of the groove, and the substrate comprises a second fitting portion on the side away from the light-emitting chip, the first fitting portion and the second fitting portion forma fitting structure, the first fitting portion is one of a protrusion and a recess, and the second fitting portion is the other of the protrusion and the recess.

17. The laser module according to claim 14, wherein the groove passes through the base plate.

18. The laser module according to claim 14, wherein the laser further comprises an integrated lens, the integrated lens comprises a lens portion and a sidewall portion, the integrated lens is connected to the frame, the lens portion is located on a side of the light-emitting chip away from the substrate, and the sidewall portion is arranged around four side surfaces of the light-emitting chip that are perpendicular to the plane where the substrate is located; and
the integrated lens, the substrate, and the frame jointly form a sealed cavity accommodating the light-emitting chip.

19. The laser module according to claim 14, wherein each laser comprises a positive pin and a negative pin, the positive pin is electrically connected to a positive electrode of the light-emitting chip, and the negative pin is electrically connected to a negative electrode of the light-emitting chip;
the soldering portion comprises a positive soldering portion and a negative soldering portion, the positive pin is soldered to the positive soldering portion, and the negative pin is soldered to the negative soldering portion; and
the base plate further comprises a control circuit, a common positive electrode, and a common negative electrode, the control circuit is located inside the base plate, the common positive electrode and the common negative electrode are located on a same side of the substrate and the soldering portion, the common positive electrode is electrically connected to the control circuit and the positive soldering portion, and the common negative electrode is electrically connected to the control circuit and the negative soldering portion.

20. The laser module according to claim 1, wherein the light-emitting chip and the protective device located on the same heat sink are connected in parallel, and a length direction of the chip is defined as the length direction of the heat sink.
